(19) United States
(12) Patent Application Publication
(10) Pub. No.: US 2026/0279472 A1
(43) Pub. Date: Sep. 17, 2026

(54) MEMORY SYSTEM

(71) Applicant: Kioxia Corporation, Tokyo (JP)

(72) Inventor: Keita KIMURA, Fujisawa Kanagawa (JP)

(21) Appl. No.: 19/310,829

(22) Filed: Aug. 26, 2025

(30) Foreign Application Priority Data
Mar. 14, 2025 (JP) 2025-041788

(51) Int. Cl. G11C 16/34; G11C 16/10; G11C 16/16; G11C 16/26

(52) U.S. Cl. CPC G11C 16/3445; G11C 16/102; G11C 16/16; G11C 16/26

(57) ABSTRACT

According to one embodiment, a memory system includes a semiconductor memory device and a control device. The control device instructs write operations and erase operations. In a write operation, write loops involving supplying a program voltage to a conductive layer are performed. The program voltage is increased for each subsequent write loop in the write operation. In an erase operation, a plurality of erase loops are performed, each including supplying an erase voltage then an erase verification operation. The semiconductor memory device outputs data corresponding to an erase verification operation result to the control device. Whenever executing a write operation, the control device transmits data indicating an initial program voltage to be used in the write operation based on the erase verification operation result.

### CROSS-REFERENCE TO RELATED APPLICATION

This application is based upon and claims the benefit of priority from Japanese Patent Application No. 2025-041788, filed Mar. 14, 2025, the entire contents of which are incorporated herein by reference.

### FIELD

Embodiments described herein relate generally to a memory system.

### BACKGROUND

A memory system including a semiconductor memory device and a control device connected to the semiconductor memory device is known.

### BRIEF DESCRIPTION OF THE DRAWINGS

FIG. 1 is a schematic block diagram o showing a configuration of a memory system.

FIG. 2 is a schematic block diagram showing a configuration of a memory die.

FIG. 3 depicts aspects of a memory die.

FIG. 4 depicts aspects of a memory die.

FIG. 5 depicts an enlarged view of a portion of FIG. 4.

FIGS. 6A to 6C depict aspects related to a threshold voltage of a memory cell that stores multi-bit data.

FIG. 7 is a flowchart illustrating an erase flow.

FIG. 8 is a flowchart illustrating an erase operation.

FIG. 9 is a diagram illustrating a relationship between a loop count and an erase voltage.

FIG. 10 is a timing chart illustrating an erase operation.

FIG. 11 is a schematic cross-sectional view illustrating aspects related to an erase operation.

FIG. 12 is a schematic cross-sectional view illustrating aspects related to an erase verification operation.

FIG. 13 is a diagram illustrating a command set and data during an erase flow.

FIG. 14 is a flowchart illustrating a write flow.

FIG. 15 is a flowchart illustrating a write operation.

FIG. 16 is a diagram illustrating a relationship between a loop count and a program voltage.

FIG. 17 is a timing chart illustrating a program operation and a verification operation.

FIG. 18 is a schematic cross-sectional view illustrating aspects related to a program operation.

FIG. 19 is a schematic cross-sectional view illustrating aspects related to a verification operation.

FIG. 20 is a schematic histogram illustrating a threshold voltage distribution of memory cells in an Er state.

FIG. 21 is a diagram illustrating a table and an example of use.

FIG. 22 is a schematic histogram illustrating a threshold voltage distribution of memory cells according to a comparative example.

FIG. 23 is a schematic histogram illustrating a threshold voltage distribution of memory cells according to a first embodiment.

FIG. 24 is a flowchart illustrating an erase flow according to a second embodiment.

FIG. 25 is a diagram illustrating a table and an example of use.

FIG. 26 is a flowchart illustrating a write flow according to a third embodiment.

FIG. 27 is a flowchart illustrating a write operation according to a third embodiment.

FIG. 28 is a timing chart illustrating a program operation and a verification operation according to a third embodiment.

FIG. 29 is a diagram illustrating a table.

FIG. 30 is a diagram illustrating a table.

### DETAILED DESCRIPTION

Embodiments provide a highly reliable memory system.

In general, according to one embodiment, a memory system includes a semiconductor memory device and a control device connected to the semiconductor memory device. The semiconductor memory device has plurality of conductive layers spaced from each other in a first direction, a semiconductor pillar extending in the first direction in the plurality of conductive layers, a charge storage layer between the plurality of conductive layers and the semiconductor pillar, and a wiring electrically connected to one end of the semiconductor pillar. The control device is configured to instruct a write operation and an erase operation of the semiconductor memory device. The write operation includes a plurality of write loops. Each of the write loops includes a program operation of supplying a program voltage to a conductive layer of the plurality of conductive layers. The program voltage increases by an offset voltage from an initial program voltage as the number write loops increases in the write operation. The erase operation includes a plurality of erase loops. Each of the erase loops includes an erase voltage supply operation of Supplying an erase voltage to the wiring and an erase verification operation executed after the erase voltage supply operation is performed. The semiconductor memory device is configured to output first data corresponding to an execution result of the erase verification operation to the control device. When executing the write operation, the control device refers to a table indicating a relationship between the first data and a magnitude to be used for the initial program voltage and transmits second data indicating the initial program voltage corresponding to the first data in the table to the semiconductor memory device.

Hereinafter, a memory system according to certain example embodiments will be described with reference to the drawings. It is to be noted that the following embodiments are only examples and are not intended to limit the scope of the present disclosure.

Throughout the description, when it is stated that a first configuration is “electrically connected” to a second configuration, the first configuration may be directly connected to the second configuration, or the first configuration may be connected to the second configuration via wiring, semiconductor member, transistors, or the like. For example, when three transistors are connected in series, the first transistor may be considered “electrically connected” to the third transistor even when the second transistor is in an OFF state.

Throughout the description, when it is stated that a first configuration is “connected between” a second configuration and a third configuration, it may mean that the first, second and third configurations are connected in series or that the second configuration is connected to the third configuration via the first configuration.

Throughout the description, when it is stated that a circuit or the like “electrically connects” two wirings, it may mean, for example, that the circuit or the like includes a transistor or the like, the transistor or the like is provided in the current path between the two wirings, and this transistor or the like is in an ON state.

Throughout the description, one direction parallel to an upper surface of a substrate is referred to as an X direction, a direction parallel to the upper surface of the substrate and perpendicular to the X direction is referred to as a Y direction, and a direction orthogonal to the upper surface of the substrate is referred to as a Z direction.

In addition, throughout the description, a direction along a given plane may be referred to as a first direction, a direction along the given plane and intersecting the first direction may be referred to as a second direction, and a direction orthogonal to the given plane may be referred to as a third direction. The first, second and third directions may or may not correspond to any of the X, Y and Z directions depending upon specific context.

Further, throughout the description, expressions such as “up” and “down” are based on the substrate as a reference. For example, a direction away from the substrate along the Z direction is referred to as an upward direction, and a direction toward the substrate along the Z direction is referred to as a downward direction. A lower surface or a lower end of a configuration may refer to a surface or end on the substrate side of the configuration, and an upper surface or an upper end may refer to a surface or end on a side opposite to the substrate of the configuration. A surface that intersects the X or Y direction may be referred to as a side surface, or the like.

### First Embodiment

### Memory System 10

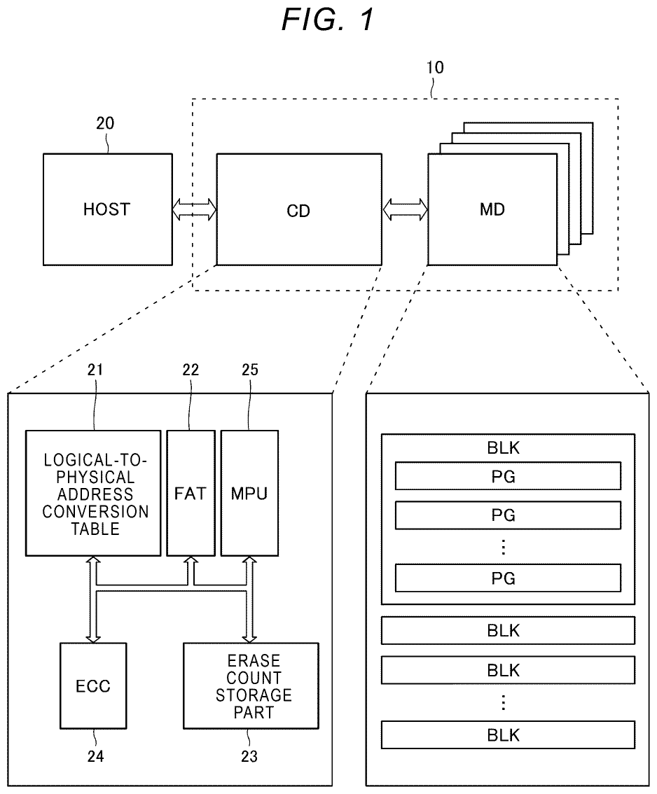

FIG. 1 is a schematic block diagram showing a configuration of a memory system 10.

The memory system 10 reads, writes, and erases user data in response to signals transmitted from a host computer 20. For example, the memory system 10 is a memory chip, a memory card, a solid-state drive (SSD) or other system capable of storing user data. The memory system 10 includes a plurality of memory dies MD (semiconductor memory devices) and a controller die CD (a control device).

The memory die MD stores the user data. The memory die MD includes a plurality of memory blocks BLK. The memory block BLK includes a plurality of pages PG. The memory block BLK may serve as a unit of execution for the erase operation. The page PG may serve as a unit of execution for the read operation and the write operation.

The controller die CD is connected to the plurality of memory dies MD and the host computer 20, as shown in FIG. 1. The controller die CD is provided with, for example, a logical-to-physical address conversion table 21, a File Allocation Table (FAT) 22, an erase count storage part 23, an ECC circuit 24, and a micro processor unit (MPU) 25. The functions of each component of the controller die CD may be implemented by either dedicated hardware, a processor executing a software program, or a combination thereof.

The logical-to-physical address conversion table 21 stores logical addresses received from the host computer 20 in association with the physical addresses assigned to the pages PG of the memory die MD. The logical-to-physical address conversion table 21 is implemented, for example, in a Random Access Memory (RAM) or the like.

The FAT 22 stores file allocation information indicating a status of each page PG. Examples of the FAT 22 stored information includes information indicating a page PG is “valid”, “invalid”, and “erased”. For example, a “valid” page PG stores valid data that can be read in response to a command from the host computer 20. An “invalid” page PG stores invalid data that is not to be read in response to a command from the host computer 20. An “erased” page PG stores no data such as after an erasing process is executed. The FAT 22 is implemented in, for example, RAM or the like.

The erase count storage part 23 stores physical addresses corresponding to the memory blocks BLK in association with the number of times an erase operation has been executed on the memory blocks BLK. The erase count storage part 23 is implemented, for example, in RAM or the like.

The ECC circuit 24 detects an error in the data as read from the memory die MD and corrects the data when possible.

The MPU 25 performs conversion between a logical address and a physical address, bit error detection/correction, garbage collection (also referred to as “compaction”), wear leveling, and the like with reference to the logical-to-physical address conversion table 21, the FAT 22, the erase count storage part 23, and the ECC circuit 24.

### Configuration of Memory Die MD

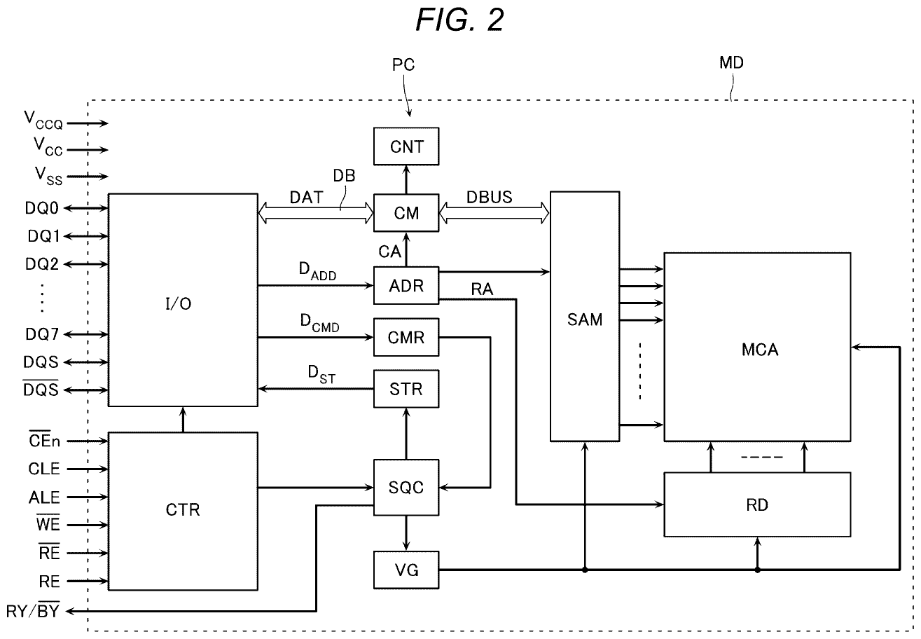

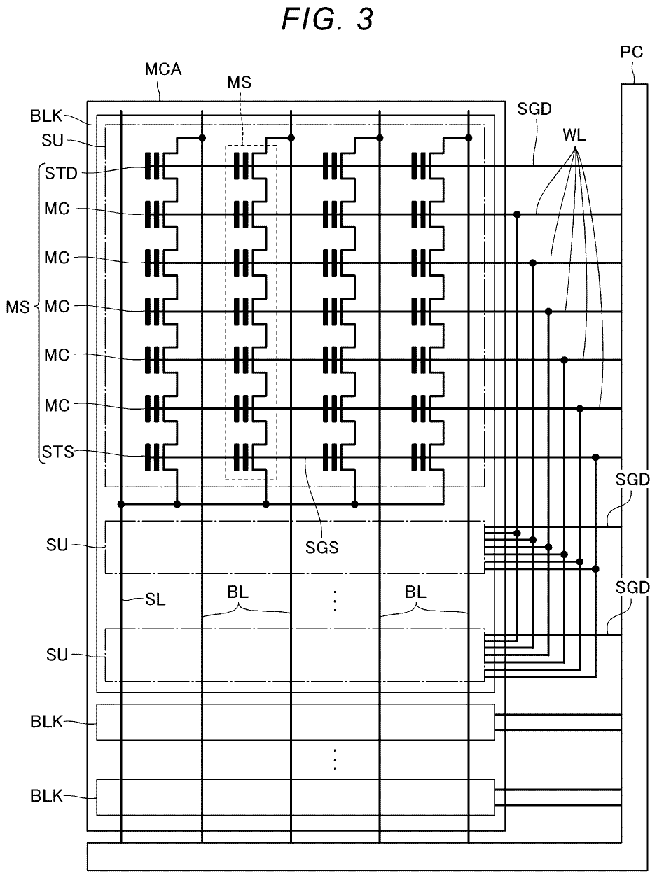

FIG. 2 is a schematic block diagram showing configuration of the memory die MD. FIG. 3 is a schematic circuit diagram showing a partial configuration of the memory die MD.

FIG. 2 illustrates a plurality of control terminals and the like on the left page side of the memory die MD. The control terminals may be control terminals corresponding to high active signals (positive logic signals), control terminals corresponding to low active signals (negative logic signals), or control terminals corresponding to both high active signal and low active signal. In FIG. 2, the symbol for a control terminal corresponding to a low active signal includes an overline of the signal name. Throughout the description, the symbol for a control terminal corresponding to a low active signal includes a slash (“/”) as a prefix on the signal/terminal name.

The description in FIG. 2 is illustrative, and specific aspects can be adjusted as appropriate. For example, it is possible to convert some or all high active signals to low active signals or some or all low active signals to high active signals. A terminal RY/(/BY) is a terminal that outputs a ready signal as the high active signal and a busy signal as the low active signal. In this context, the slash (“/”) between RY and (/BY) indicates a separation between the ready signal and the busy signal.

As shown in FIG. 2, the memory die MD includes a memory cell array MCA that stores data and a peripheral circuit PC connected to the memory cell array MCA.

### Circuit Configuration of Memory Cell Array MCA

As shown in FIG. 3, the memory cell array MCA includes a plurality of memory blocks BLK. Each of the memory blocks BLK includes a plurality of string units SU. Each of the string units SU includes a plurality of memory strings MS. One end of each of the memory strings MS is connected to the peripheral circuit PC via the bit line BL. The other end of each of the memory strings MS is connected to the peripheral circuit PC via a common source line SL.

The memory string MS includes a drain-side select transistor STD, a plurality of memory cells MC (memory transistors), and a source-side select transistor STS connected in series between the bit line BL and the source line SL. Hereinafter, the drain-side select transistor STD and the source-side select transistor STS may be referred to simply as the select transistors STD and STS.

The memory cell MC is a field-effect transistor (memory transistor) with a semiconductor layer, a gate insulating film, and a gate electrode. The semiconductor layer serves as a channel region. The gate insulating film includes a charge storage film. The threshold voltage of the memory cell MC varies depending on the amount of charge in the charge storage film. The memory cell MC stores one-bit or multi-bit data. The gate electrodes of memory cells MC corresponding to one memory string MS are each connected to different word lines WL. Each of the word lines WL is connected to all memory strings MS in the same memory block BLK.

The select transistors STD and STS are field-effect transistors with a semiconductor layer, a gate insulating film, and a gate electrode. The semiconductor layer serves as a channel region. A drain-side select gate line SGD and a source-side select gate line SGS are connected to the gate electrodes of the select transistors STD and STS, respectively. The drain-side select gate line SGD is provided corresponding to a string unit SU and is connected to all memory strings MS the same string unit SU. The source-side select gate line SGS is connected in common to all memory strings MS in the same memory block BLK. The drain-side select gate line SGD and the source-side select gate line SGS may hereinafter be referred to simply as the select gate lines SGD and SGS.

### Circuit Configuration of Peripheral Circuit PC

As shown in FIG. 2, the peripheral circuit PC includes a row decoder RD, a sense amplifier module SAM, a cache memory CM, a counter CNT, a voltage generation circuit VG, and a sequencer SQC. Further, the peripheral circuit PC includes an address register ADR, a command register CMR, and a status register STR. Further, the peripheral circuit PC includes an input/output control circuit I/O and a logic circuit CTR.

The row decoder RD (FIG. 2) includes an address decoder that decodes address data D_{ADD}. Further, the row decoder RD includes a block selection circuit and a voltage selection circuit that transfer an operating voltage to the memory cell array MCA according to the output signal of the address decoder.

For example, the sense amplifier module SAM (FIG. 2) includes a plurality of sense amplifier units. The plurality of sense amplifier units correspond to the plurality of bit lines BL. Each of the sense amplifier units includes a sense amplifier connected to a bit line BL. The sense amplifier includes a sense circuit, a latch circuit, and a voltage transfer circuit. The sense circuit includes a sense transistor and data wiring. The gate electrode of the sense transistor is electrically connected to the bit line BL. The drain electrode of the sense transistor is electrically connected to the data wiring. The sense transistor enters an ON state according to a voltage or current of the bit line BL. The data wiring is charged or discharged according to the ON/OFF state of the sense transistor. The latch circuit latches “1” or “0” data according to the voltage of the data wiring. The voltage transfer circuit electrically connects the bit line BL to one of the two voltage supply lines according to the data latched in the latch circuit.

The cache memory CM (FIG. 2) includes a plurality of latch circuits. The plurality of latch circuits of the cache memory CM are connected to latch circuits of the sense amplifier module SAM via wiring DBUS. The data DAT provided in the plurality of latch circuits of the cache memory CM is sequentially transferred to the sense amplifier module SAM or the input/output control circuit I/O.

The cache memory CM is connected to a decode circuit and a switch circuit. The decode circuit decodes a column address CA stored in the address register ADR (FIG. 2). The switch circuit electrically connects a latch circuit corresponding to the column address CA to the bus DB (FIG. 2) according to the output signal of the decode circuit.

The counter CNT (FIG. 2) receives the data sequentially transferred from the latch circuit of the cache memory CM. The counter CNT also counts the number of bits indicating “0” or “1” among the bits included in the received data.

For example, the voltage generation circuit VG (FIG. 2) includes a buck circuit and a boost circuit. For example, the buck circuit is a regulator or the like. For example, the boost circuit is a charge pump circuit or the like. Each of the buck circuit and the boost circuit is connected to a power supply voltage supply line. Supply voltage V_{CC} and ground voltage V_{SS} are supplied to the voltage generation circuit VG. The voltage generation circuit VG generates a plurality of operating voltages and outputs these voltages to a plurality of voltage supply lines. The plurality of operating voltages are supplied to the bit lines BL, the source lines SL, the word lines WL, and the select gate lines SGD and SGS during read, write, and erase operations of the memory cell array MCA. The operating voltage may be appropriately adjusted according to a control signal from the sequencer SQC.

The sequencer SQC (FIG. 2) outputs internal control signals to the row decoder RD, the sense amplifier module SAM, and the voltage generation circuit VG according to the command data D_{CMD} stored in the command register CMR. The sequencer SQC also outputs status data D_{ST} indicating the status of the memory die MD to the status register STR as appropriate.

The sequencer SQC also generates ready/busy signals and outputs the signals to the terminal RY/(/BY). During a period in which the terminal RY/(/BY) is in an “L” state (busy period), access to the memory die MD is basically prohibited. During a period in which the terminal RY/(/BY) is in an “H” state (ready period), access to the memory die MD is allowed.

As shown in FIG. 2, the address register ADR is connected to the input/output control circuit I/O and stores the address data D_{ADD} input from the input/output control circuit I/O. For example, the address register ADR includes a plurality of 8-bit register rows. For example, while an internal operation such as read operation, write operation, or erase operation is being executed, the register rows store the address data D_{ADD} corresponding to the internal operation being executed.

The address data D_{ADD} includes, for example, a column address CA (FIG. 2) and a row address RA (FIG. 2). The row address RA includes, for example, a block address specifying the memory block BLK (FIG. 3), a page address specifying the string unit SU and the word line WL, a plane address specifying the memory cell array MCA (plane), and a chip address specifying the memory die MD.

The command register CMR (FIG. 2) is connected to the input/output control circuit I/O and stores command data D_{CMD} input from the input/output control circuit I/O. The command register CMR includes, for example, at least one set of 8-bit register rows. When the command data D_{CMD} is stored in the command register CMR, a control signal is transmitted to the sequencer SQC.

The status register STR (FIG. 2) is connected to the input/output control circuit I/O and stores the status data D_{ST} to be output to the input/output control circuit I/O. For example, the status register STR includes a plurality of 8-bit register rows. For example, while an internal operation such as read operation, write operation, or erase operation is being executed, the register rows store the status data D_{ST} related to the internal operation being executed. The register rows also store, for example, ready/busy information of the memory cell array MCA.

The input/output control circuit I/O (FIG. 2) includes data signal input/output terminals DQ0 to DQ7 (FIG. 2), data strobe signal input/output terminals DQS, /DQS (FIG. 2), a shift register, and a buffer circuit. The input/output control circuit I/O is supplied with a power supply voltage V_{CCQ}.

The data input through the data signal input/output terminals DQ0 to DQ7 is input from the buffer circuit to the cache memory CM, the address register ADR, or the command register CMR according to the internal control signal from the logic circuit CTR. In addition, the data output through the data signal input/output terminals DQ0 to DQ7 is input from the cache memory CM or status register STR to the buffer circuit according to the internal control signal from the logic circuit CTR.

The signals (e.g., data strobe signals and their complementary signals) input through the data strobe signal input/output terminals DQS and/DQS are used when inputting data through the data signal input/output terminals DQ0 to DQ7. The data input through the data signal input/output terminals DQ0 to DQ7 are fetched into the shift register of the input/output control circuit I/O at the timing of the rising edge (input signal switching) of the voltage of the data strobe signal input/output terminal DQS and the falling edge (input signal switching) of the voltage of the data strobe signal input/output terminal/DQS, as well as at the timing of the falling edge (input signal switching) of the voltage of the data strobe signal input/output terminal DQS and the rising edge (input signal switching) of the voltage of the data strobe signal input/output terminal/DQS.

The logic circuit CTR (FIG. 2) includes a plurality of external control terminals /CEn, CLE, ALE, /WE, /RE, RE and a logic circuit connected to this plurality of external control terminals /CEn, CLE, ALE, /WE, /RE, RE. The logic circuit CTR receives external control signals from the controller die CD via the external control terminals/CEn, CLE, ALE, /WE, /RE, RE and outputs internal control signals to the input/output control circuit I/O accordingly.

### Structure of Memory Die MD

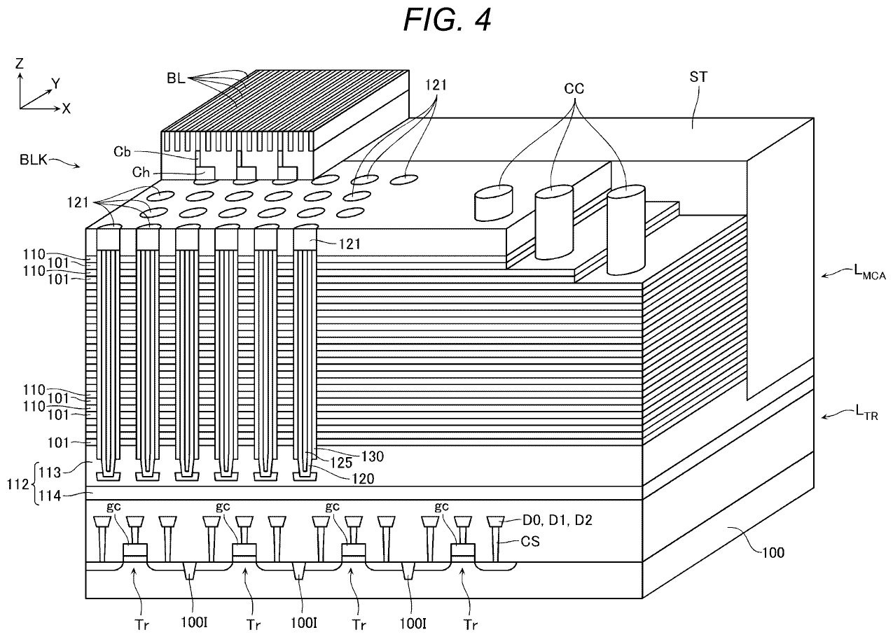

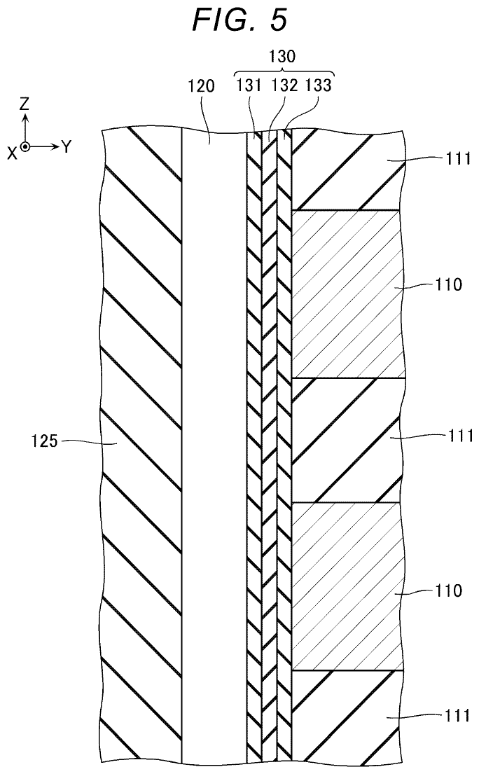

FIG. 4 is a schematic perspective view showing a partial configuration of the memory die MD. FIG. 5 is a schematic enlarged view showing a partial configuration of FIG. 4. It is to be noted that FIGS. 4 and 5 show a schematic configuration, and the specific configuration can be changed as necessary. In addition, in FIGS. 4 and 5, some aspects are omitted.

As shown in FIG. 4, the memory die MD includes a semiconductor substrate 100, a transistor layer LTR provided on the semiconductor substrate 100, and a memory cell array layer L_{MCA} provided above the transistor layer L_{TR}.

The semiconductor substrate 100 is, for example, a semiconductor substrate such as monocrystalline silicon including P-type impurities (dopants). A portion of the surface of the semiconductor substrate 100 includes an N-type well including N-type impurities (dopants) such as phosphorus (P). A portion of a surface of the N-type well includes a P-type well including P-type impurities such as boron (B). In addition, an insulating region 100I is provided on a portion of the surface of the semiconductor substrate 100.

A plurality of transistors Tr forming the peripheral circuit PC are provided in the transistor layer L_{TR}. A source region, a drain region and a channel region of the transistors Tr are provided on the surface of the semiconductor substrate 100. The gate electrodes gc of the transistors Tr are provided in the transistor layer L_{TR}. Contacts CS are provided in the source regions, the drain regions and the gate electrodes go of the plurality of transistors Tr. The plurality of contacts CS are connected to the other transistors Tr, configurations in the memory cell array layer L_{MCA}, and the like via wirings D0, D1, and D2 in the transistor layer L_{TR}.

The memory cell array layer L_{MCA} includes a plurality of memory blocks BLK and a plurality of inter-block structures ST alternately arranged in the Y direction. £ The memory block BLK includes a plurality of conductive layers 110 and a plurality of insulating layers 101 alternately arranged in the Z direction, a plurality of semiconductor pillars 120 extending in the Z direction, and a plurality of gate insulating films 130 respectively provided between the plurality of conductive layers 110 and the plurality of semiconductor pillars 120.

Each conductive layer 110 is substantially a plate shape extending in the X and Y directions. There are a plurality of conductive layers 110 arranged in the Z direction. The conductive layer 110 may comprise, for example, a stacked film of titanium nitride (TiN) and tungsten (W), or the like. In some examples, conductive layer 110 may be a polycrystalline silicon containing impurities (dopants) such as phosphorus or boron, and the like.

One or more conductive layers 110 located at the lowest layers serve as the source-side select gate lines SGS (FIG. 3) and the gate electrodes of the plurality of source-side select transistors STS connected thereto. A plurality of conductive layers 110 located thereabove the source-side select gate line SGS serve as the word lines WL (FIG. 3) and as the gate electrodes of the plurality of memory cells MC (FIG. 3) connected thereto. One or more conductive layers 110 located thereabove the word lines serve as the drain-side select gate lines SGD and the gate electrodes of the plurality of drain-side select transistors STD (FIG. 3) connected thereto.

Contacts CC, which are connected to the conductive layers 110, are provided at the edge of the plurality of conductive layers 110 in the X direction. The contacts CC extend in the Z direction and are connected at their lower ends to terrace portions of the conductive layers 110. The contacts CC may include, for example, a stacked film of a barrier conductive film such as a titanium nitride (TiN) and a metal film such as a tungsten (W). The contacts CC are provided in the current path between the conductive layer 110 and the peripheral circuit PC (FIG. 3), respectively.

A conductive layer 112 is provided below the lowermost conductive layer 110. The conductive layer 112 includes a semiconductor layer 113 connected to lower ends of the semiconductor pillars 120 and a conductive layer 114 connected to a lower surface of the semiconductor layer 113. The semiconductor layer 113 may be, for example, polycrystalline silicon or the like containing impurities such as phosphorus (P) or boron (B). The conductive layer 114 may be, for example, a metal such as tungsten (W), a conductive layer such as tungsten silicide, or other conductive layers. In addition, an insulating layer 101 such as silicon oxide (SiO₂) is provided between the conductive layer 112 and the conductive layer 110.

The conductive layer 112 serves as the source line SL (FIG. 3). For example, the source line SL is shared by all memory blocks BLK provided in the memory cell array MCA (FIG. 3).

The plurality of semiconductor pillars 120 are arranged in the X and Y directions. The semiconductor pillars 120 comprise semiconductor films such as non-doped polycrystalline silicon (Si), for example. The semiconductor pillars 120 have a substantially cylindrical shape and include an insulating film 125 such as silicon oxide at a center (core) portion thereof. An outer peripheral surface of each semiconductor pillar 120 is surrounded by the conductive layers 110. The lower ends of the semiconductor pillars 120 are connected to the semiconductor layer 113 of the conductive layer 112. Upper ends of the semiconductor pillars 120 are connected to a bit line BL via an impurity region 121 including N-type impurities such as phosphorus (P) and contacts Ch and Cb. Each of the semiconductor pillars 120 serves as the channel region for the plurality of memory cells MC and select transistors STD and STS provided in a single memory string MS (FIG. 3).

As shown in FIG. 5, the gate insulating film 130 can include a tunnel insulating film 131, a charge storage film 132, and a block insulating film 133, which are stacked between the semiconductor pillars 120 and the conductive layers 110. The tunnel insulating film 131 and the block insulating film 133 are insulating films such as silicon oxide. For example, the charge storage film 132 is a silicon nitride (SiN) film and is a film capable of storing an electric charge supplied thereto. The tunnel insulating film 131, the charge storage film 132, and the block insulating film 133 have a substantially cylindrical shape and extend along the outer peripheral surface of the semiconductor pillar 120 in the Z direction.

Although FIG. 5 shows an example in which the gate insulating film 130 includes the charge storage film 132 that is a silicon nitride or the like, the gate insulating film 130 may be provided with a floating gate structure such as polycrystalline silicon region containing N-type or P-type impurities, for example.

For example, the inter-block structures ST extend in the X and Z directions as shown in FIG. 4. The inter-block structure ST may include an insulating layer such as silicon oxide (SiO₂), for example. The inter-block structure ST may also include, for example, a conductive layer extending in the X and Z directions that is connected to the conductive layer 112 with an insulating layer such as silicon oxide (SiO₂) being on both sides of this conductive layer in the Y direction.

### Threshold Voltage of Memory Cell MC Storing a Plurality of Bits

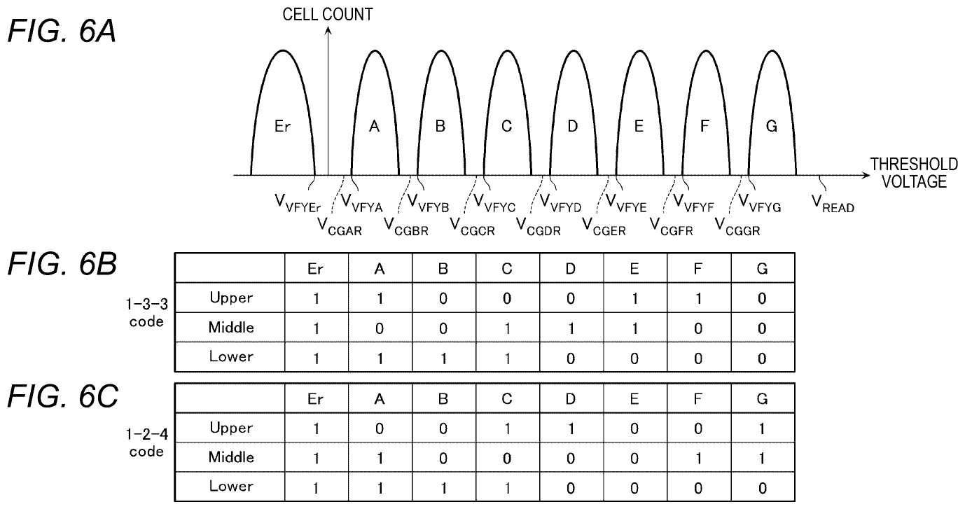

Next, the threshold voltage of a memory cell MC that stores multi-bit data will be described with reference to FIGS. 6A to 6C. FIGS. 6A to 6C show, as an example, a threshold voltage of the memory cell MC that stores 3-bit data.

FIG. 6A is a schematic histogram illustrating the threshold voltage of the memory cell MC storing 3-bit data. The horizontal axis represents a voltage of the word line WL, and the vertical axis represents the number of memory cells MC. FIG. 6B is a table showing an example of a relationship (encoding) between the threshold voltage of the memory cell MC storing 3-bit data and the data to be stored. FIG. 6C is a table showing another example of a relationship (encoding) between the threshold voltage of the memory cell MC storing 3-bit data and the data to be stored.

In FIG. 6A, the threshold voltage of the memory cell MC is controlled to eight different states. The threshold voltage of the memory cell MC controlled to Er state is lower than an erase verification voltage V_{VFYEr}. The threshold voltage of the memory cell MC controlled to A state is higher than a verification voltage V_{VFYA} but lower than a verification voltage V_{VFYB}. The threshold voltage of memory cell MC controlled to B state is greater than the verification voltage V_{VFYB} but lower than a verification voltage V_{VFYC}. In the same manner, the threshold voltage of the memory cell MC controlled to C state to F state is respectively higher than verification voltages V_{VFYC} through V_{VFYF} but respectively lower than verification voltages V_{VFYD} through V_{VFYG}. The threshold voltage of the memory cell MC controlled to G state is higher than the verification voltage V_{VFYG} but lower than a read pass voltage V_{READ}. The read pass voltage V_{READ} is, for example, a voltage of about 9 V.

In FIG. 6A, a read voltage V_{CGAR} is set between a threshold voltage distribution corresponding to the Er state and a threshold voltage distribution corresponding to the A state. A read voltage V_{CGBR} is set between the threshold voltage distribution corresponding to the A state and the threshold voltage distribution corresponding to the B state. Likewise, read voltages V_{CGCR} through V_{CGGR} are set between the threshold voltage distribution corresponding to the B state and the threshold voltage distribution corresponding to the C state, and between the threshold voltage distribution corresponding to the F state and the threshold voltage distribution corresponding to the G state, respectively.

In this example, the Er state corresponds to the lowest threshold voltage. The memory cell MC in Er state is a memory cell MC in the erased state. The memory cell MC in Er state is assigned data “111”, for example.

The A state corresponds to a higher threshold voltage than the Er state. The memory cell MC in A state is assigned data “101”, for example.

The B state corresponds to a higher threshold voltage than the A state. The memory cell MC in B state is assigned data “001”, for example.

Likewise, the C state to G state correspond to higher threshold voltages than the threshold voltages corresponding to the B state to F state. The memory cells MC in these states are assigned data “011”, “010”, “110”, “100”, and “000”, for example.

In the case of the assignment (encoding) shown in FIG. 6B, the data of the lower bit can be determined by use of one read voltage V_{CGDR}, the data of the middle bit can be determined by use of three read voltages V_{CGAR}, V_{CGCR}, and V_{CGFR}, and the data of the upper bit can be determined by sue of three read voltages V_{CGBR}, V_{CGER}, and V_{CGGR}. This data assignment may be referred to as a 1-3-3 code.

The number of bits of data to be stored in the memory cell MC, the number of states, and the data assignment to each state can be changed as needed.

For example, in the case of the assignment (encoding) illustrated in FIG. 6C, the data of the lower bit can be determined by use of one read voltage V_{CGDR}, the data of the middle bit can be determined by use of two read voltages V_{CGBR} and V_{CGFR}, and the data of the upper bit can be determined by use of four read voltages V_{CGAR}, V_{CGCR}, V_{CGER}, and V_{CGGR}. This data assignment may be referred to as a 1-2-4 code.

### Operation

Next, the operation of the memory system 10 according to the present embodiment will be described.

### Erase Flow

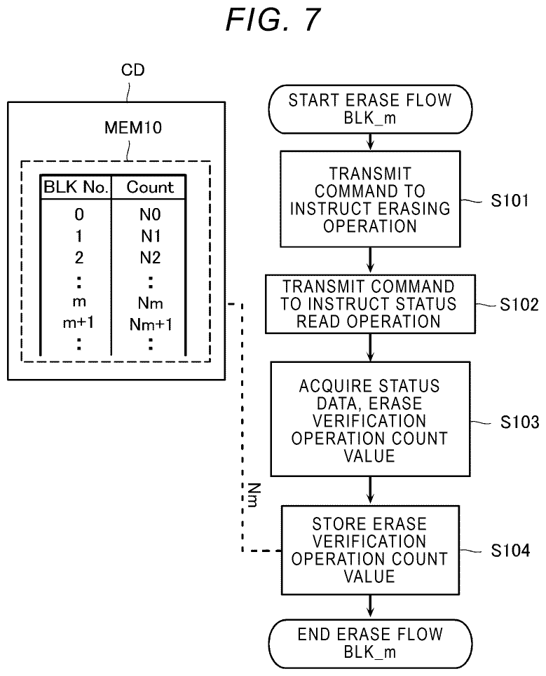

FIG. 7 is a flowchart illustrating an erase flow for the first embodiment. FIG. 7 shows the operation of the controller die CD when executing the erase flow. In the following description, an example of executing the erase flow for a memory block BLK_m that is the target of the operation will be described.

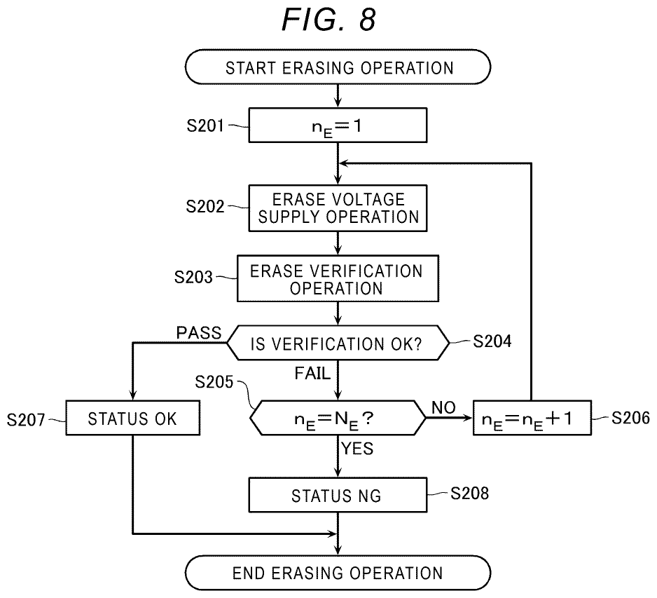

In step S101 (FIG. 7), the controller die CD transmits, to the memory die MD, a command instructing execution of an erase operation (see FIG. 8).

In step S102 (FIG. 7), the controller die CD transmits, to the memory die MD, a command instructing execution of a status read operation.

In step S103 (FIG. 7), the controller die CD acquires, from the memory die MD, the status data D_{ST} indicating whether the erase operation has been completed successfully and a count value Nm for the number of erase verification fail bits in the erase verification operation (see FIG. 8).

In step S104 (FIG. 7), the controller die CD stores the count value Nm acquired in step S103 in an area of a storing area MEM10 corresponding to the particular memory block BLK_m. The storing area MEM10 is, for example, RAM or the like provided in the controller die CD.

In the example shown in FIG. 7, the count value Nm is stored in the area of the storing area MEM10 corresponding to the m-th memory block BLK_m (where m is an integer greater than or equal to 0).

### Erase Operation

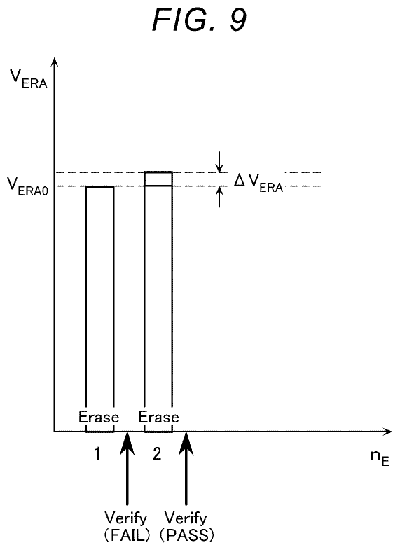

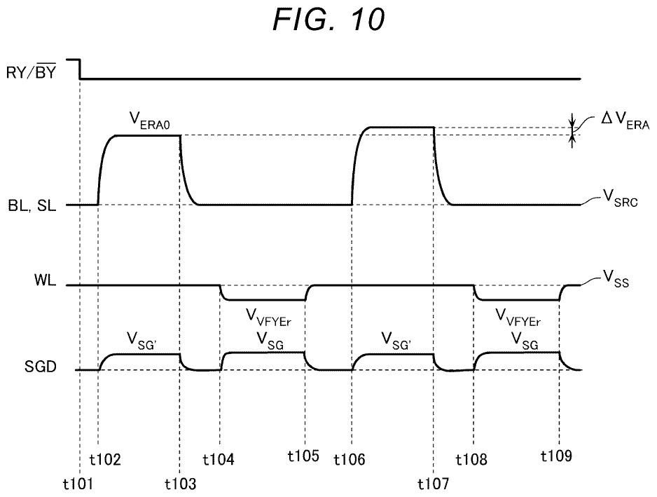

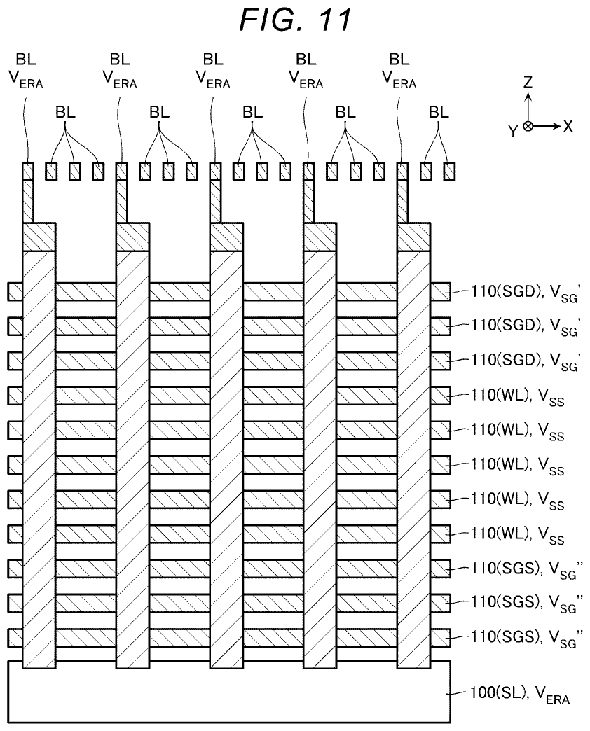

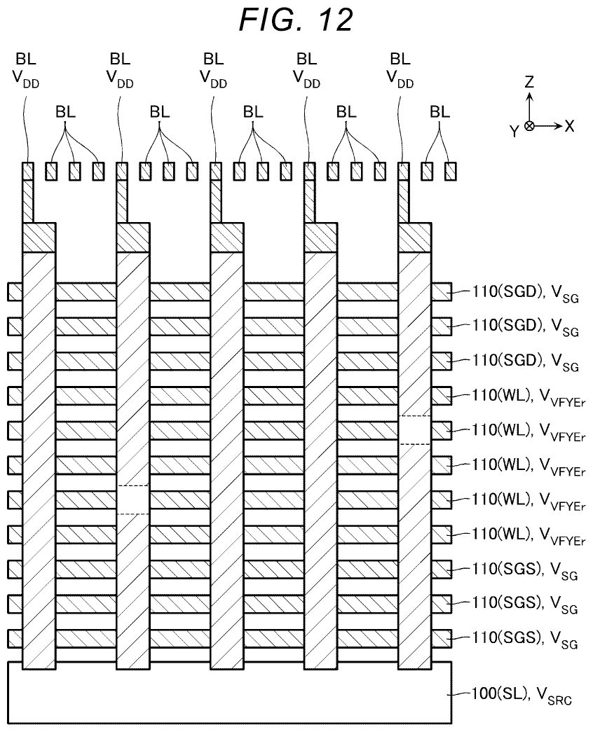

FIG. 8 is a flowchart illustrating the erase operation. FIG. 9 is a diagram illustrating the relationship between a loop count n_{E} and an erase voltage V_{ERA}. FIG. 10 is a timing chart illustrating the erase operation. FIG. 11 is a schematic cross-sectional view illustrating aspects related to the erase operation. FIG. 12 is a schematic cross-sectional view illustrating aspects related to the erase verification operation.

FIG. 8 shows the operation of the memory die MD when executing an erase operation. The erase operation includes a plurality of erase loops. Each of the erase loops includes an erase voltage supply operation (step S202) to decrease the threshold voltage of memory cell MC and an erase verification operation (step S203) to check the threshold voltage of the memory cell MC.

In step S201 (FIG. 8), the loop count ng is set to 1 (initialized). This operation is executed, for example, at timing t101 in FIG. 10. The loop count n_{E} is a variable that indicates the number of erase loops that have been performed in current erase operation.

At timing t101 (FIG. 10), with the start of the erase operation, a ready/busy signal output from the terminal RY/(/BY) transitions to “L” state (busy), and access to the memory die MD is prohibited.

In step S202 (FIG. 8), the erase voltage supply operation is executed. The erase voltage supply operation is an operation of supplying a ground voltage V_{SS} to the word line WL and supplying an erase voltage V_{ERA} to the source line SL and the bit line BL to decrease the threshold voltage of the memory cell MC. This operation is executed during a period from timing t102 to timing t103 and a period from timing t106 to timing t107 in the example in FIG. 10.

In the erase voltage Supply operation, the erase voltage V_{ERA} is supplied to the bit line BL and the source line SL as shown in FIG. 11, for example. The erase voltage V_{ERA} is, for example, a voltage of about 17 V to 25 V.

In the erase voltage supply operation, a voltage V_{SG}′ is supplied to the drain-side select gate line SGD as shown in FIG. 11, for example. The voltage V_{SG}′ is lower than the erase voltage V_{ERA}. This causes a gate induced drain leakage (GIDL) in the drain-side select transistor STD, resulting in electron-hole pairs. The electrons move to the bit line BL-side and the holes move to the memory cell MC-side.

In the erase voltage supply operation, a voltage V_{SG}″ is supplied to the source-side select gate line SGS as shown in FIG. 11, for example. The voltage V_{SG}″ is lower than the erase voltage V_{ERA}. This causes GIDL in the source-side select transistor STS, resulting in electron-hole pairs. The electrons move to the source line SL-side and the holes move to the memory cell MC-side.

In the erase voltage supply operation, a ground voltage V_{SS} is supplied to the word line WL as shown in FIGS. 10 and 11. This causes the holes in the channel of semiconductor pillar 120 to tunnel into the charge storage film 132 (FIG. 5) via the tunnel insulating film 131 (FIG. 5). This decreases the threshold voltage of the memory cell MC.

In step S203 (FIG. 8), the erase verification operation is executed. The erase verification operation is an operation of supplying the erase verification voltage V_{VFYEr} (see FIGS. 6A to 6C) to the selected word line WL_{S} and detecting ON/OFF state of the memory cell MC to detect whether the threshold voltage of the memory cell MC reaches a target value. This operation is executed during a period from timing t104 to timing t105 and a period from timing t108 to timing t109 in the example in FIG. 10.

In the erase verification operation, a voltage V_{DD} is supplied to the bit line BL as shown in FIG. 12, for example. In addition, a voltage V_{SRC} is supplied to the source line SL. The voltage V_{DD} is higher than the voltage V_{SRC}. The voltage V_{SRC} may be higher than or equal to the ground voltage V_{SS}.

In the erase verification operation, a voltage V_{SG} is supplied to the drain-side select gate line SGD as shown in FIG. 12, for example. The voltage V_{SG} is higher than the voltage V_{DD}. The voltage difference between the voltage V_{SG} and the voltage V_{DD} is greater than the threshold voltage when the drain-side select transistor STD serves as an NMOS transistor. Therefore, an electron channel is formed in the channel region of the drain-side select transistor STD, and the voltage V_{DD} is transferred through the same.

In the erase verification operation, the voltage V_{SG} is supplied to the source-side select gate line SGS as shown in FIG. 12. The voltage V_{SG} is higher than the voltage V_{SRC}. The voltage difference between the voltage V_{SG} and the voltage V_{SRC} is greater than the threshold voltage when the source-side select transistor STS functions as an NMOS transistor. Therefore, an electron channel is formed in the channel region of the source-side select transistor STS, and the voltage V_{SRC} is transferred through the same.

In the erase verification operation, the erase verification voltage V_{VFYEr} is supplied to the word line WL as shown in FIG. 12. As a result, as shown in FIG. 12, the memory cells MC with a threshold voltage lower than or equal to the erase verification voltage V_{VFYEr} are in the ON state, and the memory cells MC with a threshold voltage higher than the erase verification voltage V_{VFYEr} are in the OFF state. A current flows through the bit line BL connected to the memory string MS (the semiconductor pillar 120) that does not include the memory cell(s) MC in the OFF state. In addition, no current flows through the bit line BL connected to the memory string MS (the semiconductor pillar 120) that includes a memory cell MC in the OFF state. This current information is detected and acquired by the sense amplifier unit. Hereinafter, this data may be referred to as “erase verification data”.

As described above, the sense amplifier unit includes a plurality of latch circuits. Among the plurality of latch circuits, a latch circuit corresponding to a bit line BL through which the current flows stores data of “1”. Among the plurality of latch circuits, a latch circuit corresponding to a bit line BL through which no current flows stores data of “0”.

Data of “1” in a latch circuit indicates that the erase operation has been successfully executed for the memory string MS corresponding to the bit line BL (i.e., the threshold voltage of all memory cells MC in the memory string MS reached the target value). Hereinafter, a bit with the data of “1” may be referred to as an erase verification pass bit.

The data of “0” in a latch circuit indicates that the erase operation has not been successfully executed for the memory string MS corresponding to the bit line BL (i.e., the memory string MS includes a memory cell MC for which the threshold voltage has not reached the target value). Hereinafter, a bit with the data of “0” may be referred to as an erase verification fail bit. In addition, the total number of erase verification fail bits may be referred to as the number of fail bits. That is, the number of fail bits can be said to be equal to the number of memory string MS that did not pass verification.

The erase verification data is transferred from the latch circuit in the sense amplifier unit to the latch circuit in the cache memory CM (FIG. 2).

In step S204 (FIG. 8), the result of the erase verification operation is determined. For example, the erase verification data is sequentially transferred from the latch circuit in the cache memory CM to the counter CNT (FIG. 2). The counter CNT counts the number of erase verification fail bits (the number of bits with the data of “0”) in the erase verification data. The result of counting the number of erase verification fail bits may be referred to as the count value Nm. The count value Nm is transferred to the sequencer SQC, for example.

The sequencer SQC determines whether the count value Nm is less than a first reference value. When the count value Nm is determined to be greater than or equal to the first reference value, the erase verification is determined as FAIL and the process proceeds to step S205. On the other hand, when the count value Nm is determined to be less than the first reference value, the erase verification is determined as PASS, and the process proceeds to step S207.

In the example in FIG. 9, the erase verification is determined as FAIL in a first erase loop (loop count n_{E}=1) and the erase verification is determined as PASS in a second erase loop (loop count n_{E}=2).

In step S205 (FIG. 8), it is determined whether the loop count n_{E} has reached a predetermined count N_{E} (N_{E} is an integer greater than or equal to 1). When the predetermined count N_{E} is not yet reached, the process proceeds to step S206. When the predetermined count N_{E} has been reached, the process proceeds to step S208.

In step S206 (FIGS. 8), 1 is added to the loop count n_{E} and the process proceeds to S202. In addition, in step S206, a predetermined offset voltage ΔV_{ERA} can be added to an erase voltage V_{ERA0}. Thus, in this example, the erase voltage V_{ERA} increases by the offset voltage ΔV_{ERA} from the initial erase voltage V_{ERA0} as the loop count n_{E} increases as shown in FIG. 9.

In step S207 (FIG. 8), the status register STR (FIG. 2) stores status data D_{ST} indicating that the erase operation was completed successfully, and the erase operation is terminated.

In step S208 (FIG. 8), the status register STR (FIG. 2) stores status data D_{ST} indicating that the erase operation was not completed successfully, and the erase operation is terminated.

As described above, the status data D_{ST} and the count value Nm are output from the memory die MD to the controller die CD (FIG. 1) as part of the status read operation instructed in step S102 of FIG. 7.

Upon completion of the erase operation, the ready/busy signal output from the terminal RY/(/BY) transitions to “H” state (ready), allowing access to the memory die MD.

### Example of Erase Flow Command Set

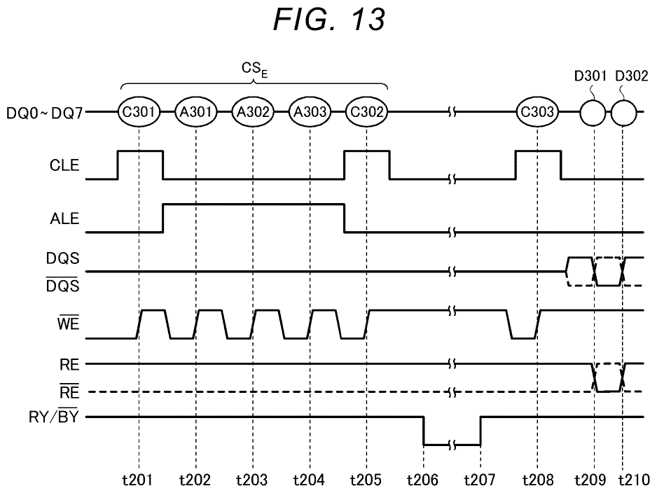

FIG. 13 is a diagram illustrating a command set and data during the erase flow (FIG. 7). The command set CS_{E} instructing the erase operation includes data C301, A301, A302, A303 and C302.

At timing t201, the controller die CD inputs the data C301 to the memory die MD as command data D_{CMD}. That is, “H” or “L” is input to the data signal input/output terminals DQ0 to DQ7 according to 8-bit data in the data C301, “H” is input to the external control terminal CLE and “L” is input to the external control terminal ALE, and then the signal of the external control terminal/WE is transitioned from “L” to “H”. The data C301 is the command input at the start of the erase operation.

At timing t202, the controller die CD inputs the data A301 to the memory die MD as address data D_{ADD}. That is, “H” or “L” is input to the data signal input/output terminals DQ0 to DQ7 according to the 8-bit data in the data A301, “L” is input to the external control terminal CLE and “H” is input to the external control terminal ALE, and then the signal of the external control terminal/WE is transitioned from “L” to “H”. The data A301 is part of the row address RA. The data A301 includes, for example, a block address that specifies a memory block BLK.

At timing t203, the controller die CD inputs the data A302 to the memory die MD as address data D_{ADD}. The data A302 is part of the row address RA. The data A302 includes, for example, a block address and a page address.

At timing t204, the controller die CD inputs the data A303 to the memory die MD as address data D_{ADD}. The data A303 includes a chip address. The chip address is data that specifies one memory die MD from among a plurality of memory dies MD controlled by the controller die CD.

At timing t205, the controller die CD inputs the data C302 to the memory die MD as command data D_{CMD}. The data C302 is a command indicating that the input of the command set for the erase operation is completed.

At timing t206, the terminal RY/(/BY) transitions from “H” state to “L” state and access to the memory die MD is prohibited. In addition, the erase operation is executed on the memory die MD. The timing t206 corresponds to the timing t101 in FIG. 10.

At timing t207, the erase operation in the memory die MD is terminated (finished). The terminal RY/(/BY) transitions from “L” state to “H” state, and access to the memory die MD is allowed. The timing t207 is later than the timing t109 in FIG. 10.

At timing t208, the controller die CD inputs data C303 to the memory die MD as command data D_{CMD}. The data C303 is a command requesting output of the status data D_{ST} stored in the status register STR (FIG. 2) and the data indicating the execution result of the erase verification operation.

At timing t209, the controller die CD outputs data D301 from the memory die MD. That is, one of the signals of the external control terminals RE and/RE is transitioned from “L” to “H”. In addition, the other of the external control terminals RE and/RE is transitioned from “H” to “L”. In this example, the data D301 is the status data D_{ST}.

At timing t210, the controller die CD outputs data D302 from the memory die MD. In this example, data D302 is data indicating the execution result of the erase verification operation, e.g., the count value Nm of the number of the erase verification fail bits.

### Write Flow

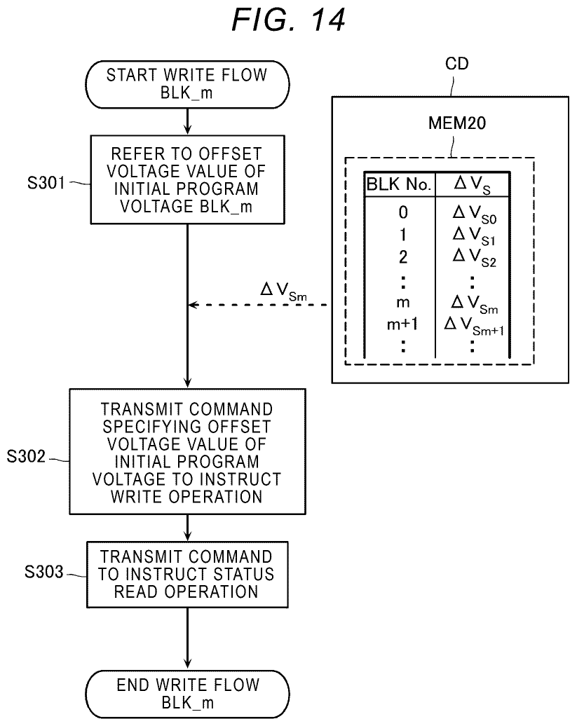

FIG. 14 is a flowchart illustrating a write flow. FIG. 14 shows the operation of the controller die CD when executing the write flow. In the following description, an example of executing a write operation to the memory cell MC provided in the memory block BLK_m, which is the target of the operation, will be described.

In step S301 (FIG. 14), the controller die CD refers to a storing area MEM20 to acquire the offset voltage ΔV_{Sm} corresponding in particular to the memory block BLK_m. It is to be noted that, in the following description, the offset voltage ΔV_{S} corresponding to the memory block BLK_m in particular may be referred to as the offset voltage ΔV_{Sm}. The storing area MEM20 is, for example, RAM or the like provided in the controller die CD.

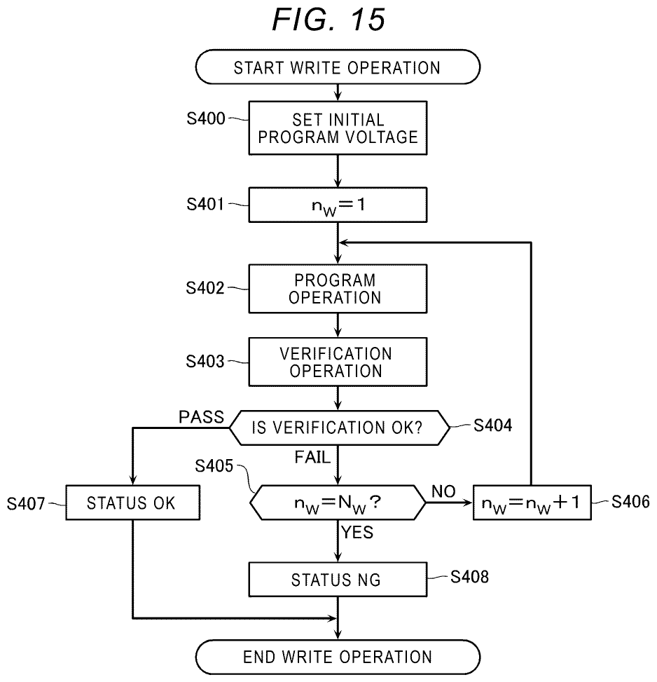

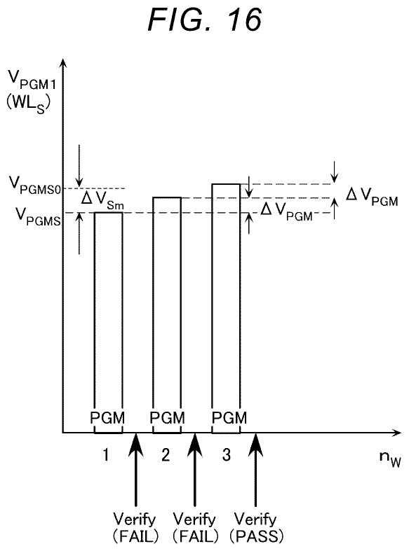

In step S302 (FIG. 14), the controller die CD transmits a command specifying the offset voltage ΔV_{Sm} with respect to an initial program voltage V_{PGMS} to the memory die MD and instructing a write operation (FIG. 15). As a result, for the memory die MD, an initial program voltage V_{PGMS} obtained by adding the offset voltage ΔV_{Sm} to a reference initial program voltage V_{PGMS0} is set and the write operation (FIG. 16) is started.

In step S303 (FIG. 14), the controller die CD transmits a command to the memory die MD instructing it to execute a status read operation. As a result, the controller die CD acquires, from the memory die MD, the status data D_{ST} indicating whether the write operation was completed successfully.

### Write Operation

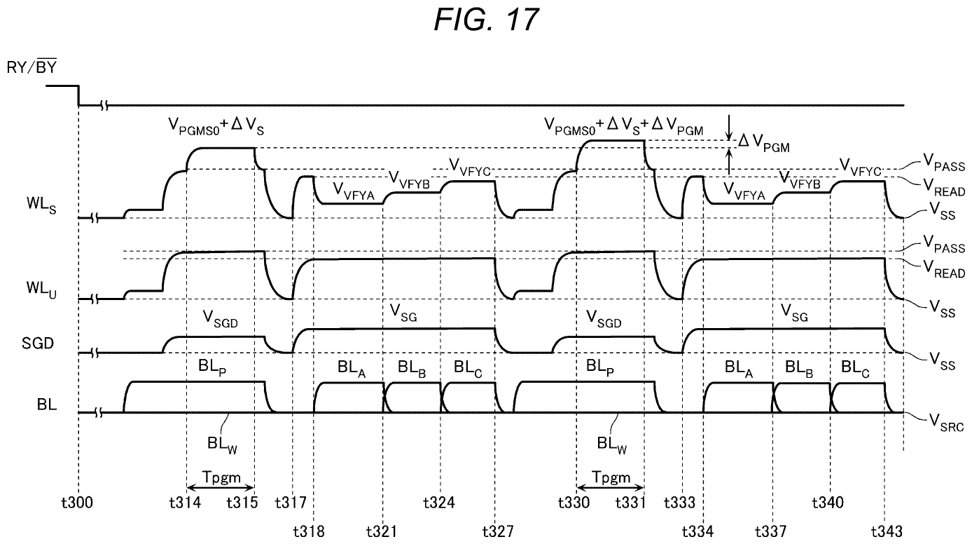

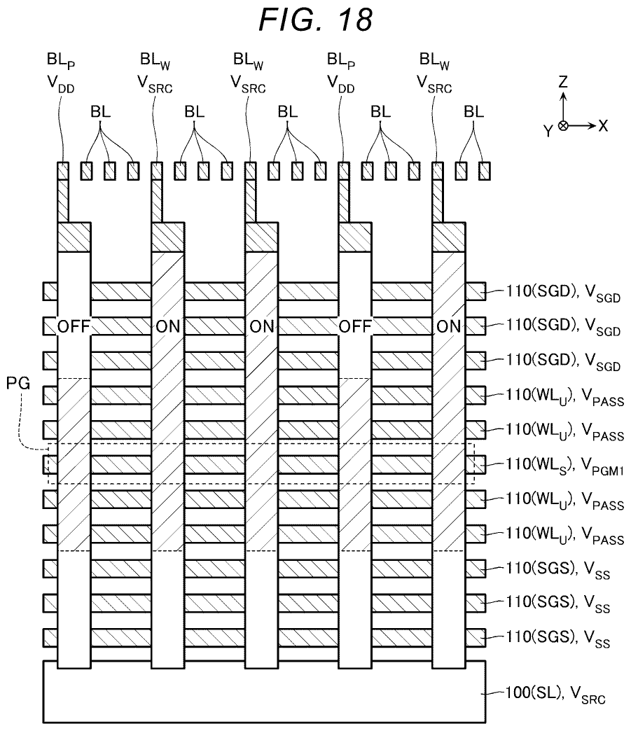

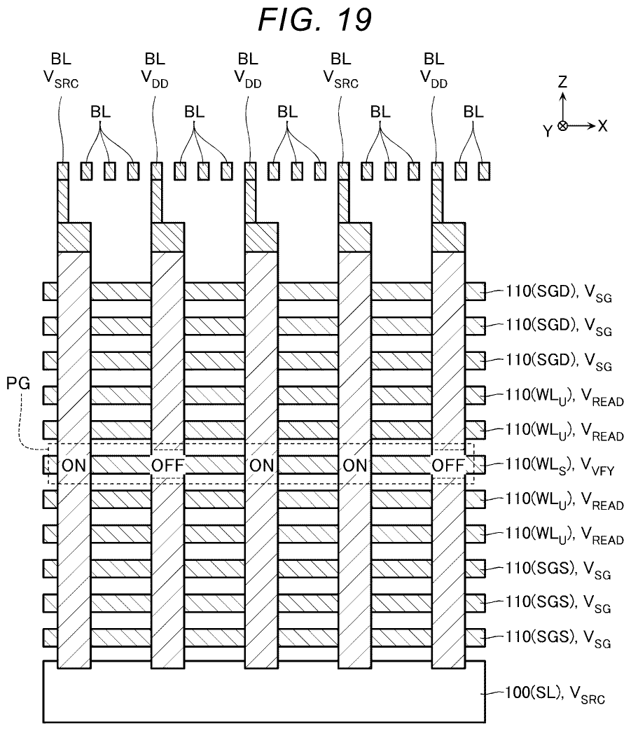

Next, the write operation of the memory system 10. FIG. 15 is a flowchart illustrating a write operation according to the first embodiment. FIG. 16 is a diagram illustrating the relationship between a loop count n_{W} and a program voltage V_{PGM1}. FIG. 17 is a timing chart illustrating a program operation and a verification operation. FIG. 18 is a schematic cross-sectional view illustrating aspects related to the program operation. FIG. 19 is a schematic cross-sectional view illustrating aspects related to the verification operation.

In the following description, a word line WL that is the target of the program operation may be referred to as the selected word line WL_{S}, and other (non-targeted) word lines WL may be referred to as the non-selected word lines WL_{U}. In the following description, among the plurality 44 memory cells MC provided in the string unit SU that is the target of operation, a memory cell MC connected to a selected word line WL_{S} may be referred to as a “selected memory cell MC”. In addition, in the following description, a grouping including a plurality of selected memory cells MC may be referred to as a selected page PG.

In the following description, an example of executing the write operation on a plurality of selected memory cells MC corresponding to the selected page PG will be described.

The write operation includes a plurality of write loops. Each write loop includes a program operation (step S402 in FIG. 15) to increase the threshold voltage of the memory cell MC and a verification operation (step S403 in FIG. 15) to check the threshold voltage of the memory cell MC.

In step S400, the initial program voltage V_{PGMS} (FIG. 16) is set. The initial program voltage V_{PGMS} is the initial voltage for the program voltage V_{PGM1} in the program operation (step S402). A voltage V_{PGMS0}+ΔV_{Sm} obtained by adding the offset voltage ΔV_{Sm} specified in step S302 (FIG. 14) to the reference initial program voltage V_{PGMS0} is set to the initial program voltage V_{PGMS}. FIG. 16 shows an example when the offset voltage ΔV_{Sm} is a negative value.

In step S401, the loop count n_{W} is set to 1 (initialized). The loop count n_{W} is a variable indicating the number of write loops that have been performed in sequence. In step S401, the data to be written to the memory cell MC is latched into the latch circuit in the sense amplifier unit. The operations of steps S400 and S401 are executed, for example, at timing t300 in FIG. 17.

In step S402, the program operation is executed. The program operation is an operation of increasing the threshold voltage of the memory cell MC by supplying the program voltage V_{PGM1} to the selected word line WL_{S}. This operation is executed during a period from timing t314 to timing t315 and a period from timing t330 to timing t331 in the example in FIG. 17.

In the program operation, as shown in FIGS. 17 and 18, the voltage V_{SRC} is supplied to the bit line BL_{W} connected to a selected memory cell MC that is to have its threshold voltage adjusted. The voltage V_{DD} is supplied to the bit line BL_{P} connected to a selected memory cell MC that is not to have its the threshold voltage adjusted. Hereinafter, among the plurality of selected memory cells MC, a selected memory cell MC which is to have its threshold voltage adjusted may be referred to as a “write memory cell MC” and a selected memory cell MC that is not to have its threshold voltage adjusted may be referred to as an “inhibited memory cell MC”.

In the program operation, a voltage V_{SGD} is supplied to the drain-side select gate line SGD, as shown in FIGS. 17 and 18.

The voltage V_{SGD} is higher than the voltage V_{SRC}. The voltage difference between the voltage V_{SGD} and the voltage V_{SRC} is greater than the threshold voltage when the drain-side select transistor STD serves as an NMOS transistor. Therefore, an electron channel is formed in the channel region of the drain-side select transistor STD connected to the bit line BL_{W}, and the voltage V_{SRC} is transferred through the same.

The voltage difference between the voltage V_{SGD} and the voltage V_{DD} is less than the threshold voltage when the drain-side select transistor STD serves as an NMOS transistor. Therefore, the drain-side select transistor STD connected to the bit line BL_{P} is in the OFF state.

In the program operation, as shown in FIG. 18, the voltage V_{SRC} is supplied to the source line SL and the ground voltage V_{SS} is supplied to the source-side select gate line SGS. As a result, the source-side select transistor STS is in the OFF state.

In addition, in the program operation, a write pass voltage V_{PASS} is supplied to the non-selected word line WL_{U}, as shown in FIGS. 17 and 18. The write pass voltage V_{PASS} is greater than the read pass voltage V_{READ} described with reference to FIGS. 6A to 6C. The write pass voltage V_{PASS} is, for example, a voltage of about 10 V. The voltage difference between the write pass voltage V_{PASS} and the voltage V_{SRC} is greater than the threshold voltage when the memory cell MC serves as an NMOS transistor, regardless of the data stored in the memory cell MC. Therefore, an electron channel is formed in the channel region of the non-selected memory cell MC connected to the bit line BL_{W}, and the voltage V_{SRC} is transferred to the write memory cell MC through the same.

In addition, in the program operation, the program voltage V_{PGM1} is supplied to the selected word line WL_{S}, for example, as shown in FIGS. 17 and 18. The program voltage V_{PGM1} is higher than the write pass voltage V_{PASS}.

In this example, the voltage V_{SRC} is supplied to the channel of the semiconductor pillar 120 connected to the bit line BL_{W}. A relatively large electric field is generated between the semiconductor pillar 120 and the selected word line WL_{S}. This causes the electrons in the channel of semiconductor pillar 120 to tunnel into the charge storage film 132 (FIG. 5) via the tunnel insulating film 131 (FIG. 5). This increases the threshold voltage of the write memory cell MC.

The channel of the semiconductor pillar 120 connected to the bit line BL_{P} is in an electrically floating state, and the potential of this channel is increased to about the write pass voltage V_{PASS} by capacitive coupling with the non-selected word line WL_{U}. An electric field smaller than the electric field described above is generated between the semiconductor pillar 120 and the selected word line WL_{S}. Therefore, the electrons in the channel of semiconductor pillar 120 do not tunnel into the charge storage film 132 (FIG. 5). Therefore, the threshold voltage of the inhibited memory cell MC does not increase.

In the example in FIG. 17, the application time for the program voltage V_{PGM1} (from timing t314 to timing t315) is shown as time Tpgm.

FIG. 16 shows an example in which the program operation is executed over three write loops. In the program operation (from timing t314 to timing t315 in FIG. 17) in the first write loop (loop count n_{W}=1), a voltage (V_{PGMS0}+ΔV_{Sm}), which is the sum of the reference initial program voltage V_{PGMS0} and the offset voltage ΔV_{Sm}, is supplied to the selected word line WL_{S}. As described above, the voltage V_{PGMS0}+ΔV_{Sm} is the voltage that is set as the initial value of the program voltage V_{PGM1} in step S400. In the program operation (from timing t330 to timing t331 in FIG. 17) in the second write loop (loop count n_{W}=2), a voltage V_{PGMS0}+ΔV_{Sm}+ΔV_{PGM} obtained by adding the offset voltage ΔV_{PGM} to the initial program voltage V_{PGMS} (=voltage V_{PGMS0}+ΔV_{Sm}) is supplied to the selected word line WL_{S} as the program voltage V_{PGM1}.

In the program operation in the third write loop, which is not specifically depicted in FIG. 17, a voltage V_{PGMS0}+ΔV_{Sm}+2ΔV_{PGM} obtained by adding twice the offset voltage ΔV_{PGM} to the initial program voltage V_{PGMS} (=voltage V_{PGMS0}+ΔV_{Sm}) is supplied to the selected word line WL_{S} as the program voltage V_{PGM1}.

In step S403 (FIG. 15), the verification operation is executed. The verification operation is an operation of supplying the verification voltage V_{VFY} to the selected word lines WL_{S} and detecting ON/OFF state of the memory cells MC to detect whether the threshold voltage of the targeted memory cells MC reaches the target value. This operation is executed during a period from timing t317 to timing t327 and a period from timing t333 to timing t343 in the example in FIG. 17.

In the verification operation, whether the threshold voltage reaches the target value can be detected for a memory cell MC corresponding to one or a plurality of states, as shown in FIGS. 17 and 19, for example.

In FIG. 17, during the first verification operation from timing t318 to timing t321, whether the threshold voltage reaches the target value is detected for a memory cell MC corresponding to the A state. From timing t321 to timing t324, whether the threshold voltage reaches the target value is detected for a memory cell MC corresponding to the B state. From the timing t324 to timing t327, whether the threshold voltage reaches the target value is detected for a memory cell MC corresponding to the C state.

For example, in the operation corresponding to the A state, as shown in FIGS. 17 and 19, the voltage V_{DD} is supplied to the bit line BL (bit line BL_{A} in the examples in FIGS. 17 and 19) connected to the memory cell MC corresponding to the A state, and the voltage V_{SRC} is supplied to the other bit lines BL.

In addition, in the operation corresponding to the A state, the voltage V_{SG} is supplied to the drain-side select gate line SGD, as shown in FIGS. 17 and 19. The voltage V_{SG} is higher than the voltage V_{DD}. The voltage difference between the voltage V_{SG} and the voltage V_{DD} is greater than the threshold voltage when the drain-side select transistor STD serves as an NMOS transistor. Therefore, an electron channel is formed in the channel region of the drain-side select transistor STD, and the voltage V_{DD} is transferred through the same.

In addition, in the operation corresponding to the A state, the voltage V_{SG} is supplied to the source-side select gate line SGS, as shown in FIG. 19. The voltage V_{SG} is higher than the voltage V_{SRC}. The voltage difference between the voltage V_{SG} and the voltage V_{SRC} is greater than the threshold voltage when the source-side select transistor STS serves as an NMOS transistor. Therefore, an electron channel is formed in the channel region of the source-side select transistor STS, and the voltage V_{SRC} is transferred through the same.

In addition, in the operation corresponding to the A state, the read pass voltage V_{READ} is supplied to the non-selected word line WL_{U}, as shown in FIGS. 17 and 19. The read pass voltage V_{READ} is higher than the voltages V_{DD} and V_{SRC}. The voltage difference between the read pass voltage V_{READ} and the voltages V_{DD} and V_{SRC} is greater than the threshold voltage when the memory cell MC serves as an NMOS transistor, regardless of the data stored in the memory cell MC. Therefore, an electron channel is formed in the channel region of the non-selected memory cell MC, and the voltages V_{DD} and V_{SRC} are transferred to the selected memory cell MC through the same.

In addition, in the operation corresponding to the A state, the verification voltage V_{VFYA} is supplied to the selected word line WL_{S}. As a result, as shown in FIG. 19, the memory cells MC with the threshold voltage less than or equal to the verification voltage V_{VFYA} are in the ON state, and the memory cells MC with the threshold voltage greater than the verification voltage V_{VFYA} are in the OFF state. A current flows through the bit line BL connected to the memory cells MC in the ON state. No current flows through the bit line BL connected to a memory cell MC in the OFF state. This current information is detected and acquired by the sense amplifier unit. Hereinafter, this data may be referred to as “verification data”.

As described above, the sense amplifier unit includes a plurality of latch circuits. Among the plurality of latch circuits, a latch circuit corresponding to a bit line BL through which the current flows stores data of “1”. Among the plurality of latch circuits, a latch circuit corresponding to a bit line BL through which no current flows stores data of “0”.

The data of “1” indicates that data was not written successfully to a selected memory cell MC corresponding to the bit line BL (i.e., the threshold voltage of the selected memory cell MC does not reach the target value). In this context, a bit with the data of “1” may be referred to as a verification fail bit.

The data of “0” indicates that data was written successfully to the selected memory cell MC corresponding to a bit line BL (i.e., the threshold voltage of the selected memory cell MC reached the target value). In this context, a bit with the data of “0” may be referred to as a verification pass bit.

The verification data is transferred from the latch circuit in the sense amplifier unit to the latch circuit in the cache memory CM (FIG. 2).

In step S404 (FIG. 15), the result of the verification operation is determined. For example, the verification data is sequentially transferred from the latch circuit in the cache memory CM to the counter CNT (FIG. 2). The counter CNT counts the number of verification fail bits (the number of bits with the data of “1”) in the verification data. The result of counting the number of verification fail bits can be transferred to the sequencer SQC.

The sequencer SQC determines whether the number of verification fail bits in the verification data is less than a second reference value. When the number of verification fail bits is less than the second reference value, the sequencer SQC determines verification PASS and proceeds to step S407. On the other hand, when the number of verification fail bits is equal to or greater than the second reference value, the sequencer SQC determines verification FAIL and proceeds to step S405.

In FIG. 16, the verification is determined as FAIL in the first and second write loops (loop count n_{W}=1, 2), but determined as PASS in the third write loop (loop count n_{W}=3).

In step S405 (FIG. 15), it is determined whether the loop count n_{W} reaches a predetermined count N_{W}. When the predetermined count N_{W} is not yet reached, the process proceeds to step S406. When the predetermined count N_{W} has been reached, the process proceeds to step S408.

In step S406 (FIGS. 15), 1 is added to the loop count n_{W}, and the process proceeds to step S402. In step S406, a predetermined offset voltage ΔV_{PGM} can be added to the program voltage V_{PGM1}. Therefore, the program voltage V_{PGM1} increases by the offset voltage ΔV_{PGM} as the loop count n_{W} increases.

In step S407 (FIG. 15), the status register STR (FIG. 2) stores the status data D_{ST} indicating that the write operation was completed successfully, and the write operation is terminated (finished). The status data D_{ST} is output to the controller die CD (FIG. 1) in a status read operation.

In step S408 (FIG. 15), the status register STR (FIG. 2) stores the status data D_{ST} indicating that the write operation was not completed successfully, and the write operation is terminated.

### Index (1) of Changes in Characteristics of Memory Cell MC

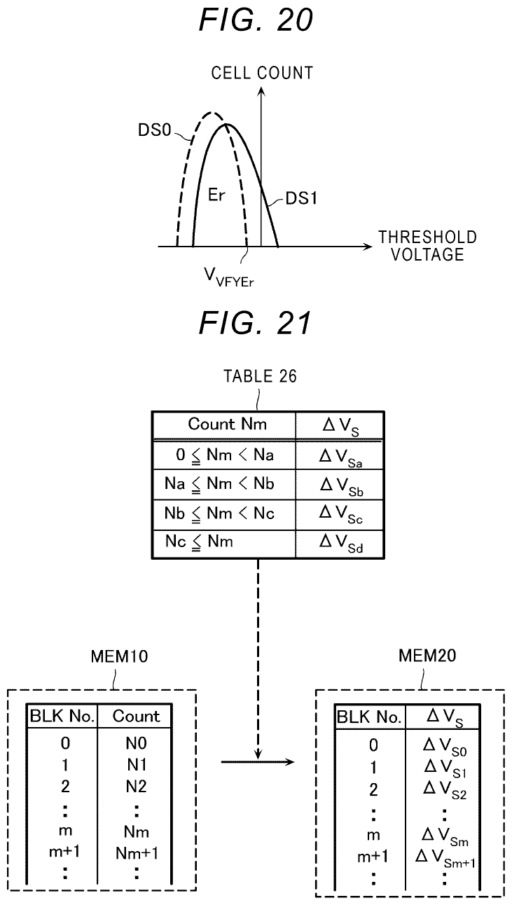

FIG. 20 is a schematic histogram illustrating the threshold voltage distribution of the memory cells MC in the Er state. FIG. 20 shows a distribution DS0 (dashed line) and a distribution DS1 (solid line) as examples of the threshold voltage distribution of the memory cells MC in the Er state. The distribution DS0 corresponds to a state before any significant changes in memory cell MC characteristics have occurred from an initial state, that is, in a state in which write operations and erase operations on the memory cells MC have hardly been performed. The distribution DS1 corresponds to state after the characteristics of the memory cells MC have changed as a result of repeatedly executing write operations and erase operations on the memory cells MC. The distribution DS1 has a wider distribution width than the distribution DS0, and the average value of the threshold voltage has shifted (drifted) toward a higher value.

Such a change in the threshold voltage distribution occurs, for example, when the write operation and the erase operation are repeatedly performed with a relatively high voltage applied to the gate insulating film 130 (FIG. 5), resulting in the generation of more crystal defects and the like inside the tunnel insulating film 131 (FIG. 5), and the trapping of more electrons in the tunnel insulating film 131. When a large number of electrons are trapped inside the tunnel insulating film 131, the threshold voltage of the memory cell MC increases due to the influence of these electrons, resulting in a change from the distribution DS0 to the distribution DS1, as shown in FIG. 20.

After the erase operation (FIG. 8) is terminated, if the threshold voltage distribution of memory cells MC in the Er state is in a state similar to the distribution DS1, then when determining the result of the erase verification operation (FIG. 8, step S204), the number of memory cells MC with the threshold voltage higher than the erase verification voltage V_{VFYEr} increases, and the count value Nm of the number of fail bits in the erase verification operation increases.

Therefore, the count value Nm serves as an index value for changes in the characteristics of the memory cells MC over time or with use. In general, the larger the count value Nm, the more the threshold voltage distribution of the memory cells MC shifts toward higher values, and it can be identified that the characteristics are changing.

### Table 26 Showing Relationship Between Count Value Nm and Magnitude of Initial Program Voltage V_{PGMS}

FIG. 21 is a diagram illustrating the table 26 and an example of use of table 26. The table 26 shows the relationship between the count value Nm and the magnitude of the initial program voltage V_{PGMS}.

In the example shown in FIG. 21, when the count value Nm is equal to or greater than index value 0 but less than index value Na, the offset voltage ΔV_{S} is set to an offset voltage ΔV_{Sa}. Likewise, when the count value Nm is equal to or greater than the index value Na but less than index value Nb, the offset voltage ΔV_{S} is set to an offset voltage ΔV_{Sb}. When the count value Nm is equal to or greater than the index value Nb but less than index value Nc, the offset voltage ΔV_{S} is set to an offset voltage ΔV_{Sc}. When the count value Nm is equal to or greater than the index value Nc, the offset voltage ΔV_{S} is set to an offset voltage ΔV_{Sd}.

It is to be noted that in the table 26, the offset voltages ΔV_{Sa}, ΔV_{Sb}, ΔV_{Sc}, and ΔV_{Sa} may be negative values, for example, and their absolute values may be the offset voltages ΔV_{Sa}, ΔV_{Sb}, ΔV_{Sc}, and ΔV_{Sa} in ascending order. In this example, as the count value Nm increases, the initial program voltage V_{PGMS} (=voltage V_{PGMS0}+ΔV_{Sm}) is set become smaller.

As shown in the lower part of FIG. 21, by referring to the table 26, the controller die CD acquires the appropriate offset voltage ΔV_{S} corresponding to the count value Nm for each memory block BLK stored in the storing area MEM10, and stores the acquired offset voltage in the storing area MEM20 corresponding to each memory block BLK_m.

In the example shown in FIG. 21, the offset voltage ΔV_{Sm} is stored in the area of the storing area MEM20 corresponding to the m-th memory block BLK_m.

### Comparative Example

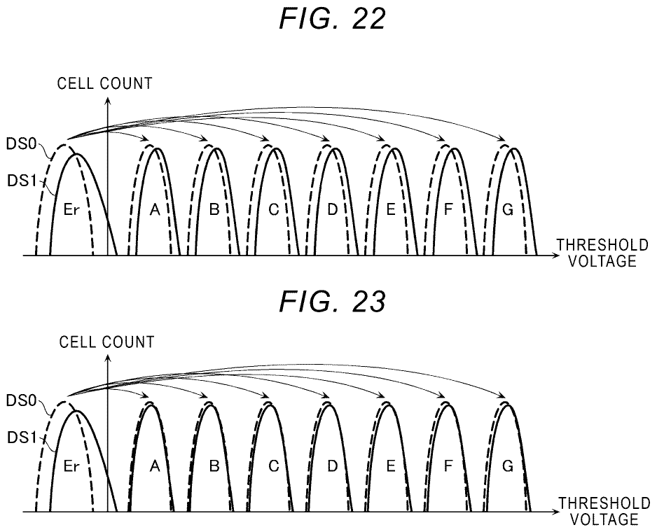

Next, a memory system according to a comparative example will be described. FIG. 22 is a schematic histogram illustrating the threshold voltage distribution of memory cells MC according to the comparative example.

In the memory system according to the comparative example, the step corresponding to step S400 in FIG. 15 is not executed in the write operation. That is, the reference initial program voltage V_{PGMS0} is always set as the initial program voltage V_{PGMS}, and unlike the present embodiment, the offset voltage ΔV_{S} is not added to the reference initial program voltage V_{PGMS0} at start of the write operation.

In the comparative example, as shown in FIG. 22, whether the threshold voltage distribution of the memory cells MC in the Er state is the distribution DS0 or the distribution DS1, the program operation is executed with the same reference initial program voltage V_{PGMS0}. In this case, for distribution DS1, the threshold voltage distribution of the memory cell MCs written in the A to G states may be too high.

### Effects

FIG. 23 is a schematic histogram illustrating the threshold voltage distribution of the memory cells MC according to the first embodiment.

In the memory system 10 according to the first embodiment, the step S400 in FIG. 15 is executed. That is, the initial program voltage V_{PGMS} is set to a value obtained by adding the offset voltage ΔV_{S} to the reference initial program voltage V_{PGMS0}, and the program operation is executed with an adjusted voltage.

As shown in FIG. 23, when the threshold voltage of the memory cells MC in the Er state has the distribution DS0, the count value Nm is generally small, and therefore, the initial program voltage V_{PGMS} can be set to a value obtained by adding 0 or the offset voltage ΔV_{S} with a relatively small absolute value to the reference initial program voltage V_{PGMS0}.

However, when the threshold voltage distribution of the memory cell MCs in the Er state is in the distribution DS1, the count value Nm is typically large, and therefore, the initial program voltage V_{PGMS} is set to a value obtained by adding the offset voltage ΔV_{S} of a relatively large absolute value to the reference initial program voltage V_{PGMS0}.

In particular, when the offset voltage ΔV_{S} is a negative value, the larger the count value Nm, thus the program operation (step S402 in FIG. 15) is executed with a smaller initial program voltage V_{PGMS}. As a result, even with the distribution DS1, it is possible to prevent the threshold voltage distribution of memory cells MC written in the A to G states from becoming excessively high.

Furthermore, by using an optimal initial program voltage V_{PGMS} (set according to the count value Nm) in the program operation (step S402 in FIG. 15), the threshold voltage distribution of memory cells MC written in the A to G states can be kept within a constant range.

In this manner, in the first embodiment, by changing the initial program voltage V_{PGMS} according to the count value Nm, good write characteristics for the memory cells MC can be maintained even when the characteristics of the memory cells MC change with use or the like.

### Second Embodiment

In the first embodiment, the count value Nm of the number of fail bits, which is the execution result of the erase verification operation, is stored in the storing area MEM10 in the controller die CD as the index of changes in the characteristics of the memory cell MC. In addition, during the write operation, an optimal initial program voltage V_{PGMS} is set according to the count value Nm.

However, such a specific method is merely one example, and for example, a cumulative loop count Lm of the erase loops executed up to the end of the erase operation (FIG. 8) may be used as the index for changes in the characteristics of the memory cells MC. Similarly, during the program operation, an optimal initial program voltage V_{PGMS} may be set according to the loop count Lm. Hereinbelow, such an example will be described as the second embodiment.

### Erase Flow

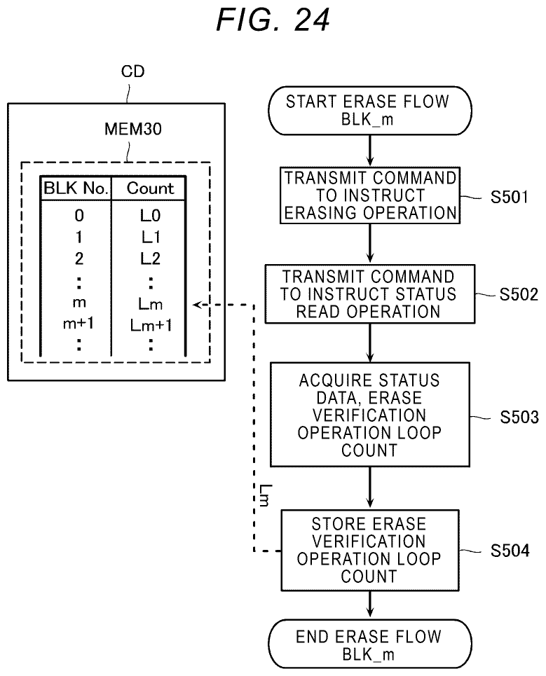

FIG. 24 Is a Flowchart Illustrating the Erase Flow

according to the second embodiment. FIG. 24 shows the operation of the controller die CD when executing the erase flow. In the following description, an example of executing the erase flow for a memory block BLK_m will be described.

In steps S501 and S502 (FIG. 24), the controller die CD performs the same operations as steps S101 and S102 (see FIG. 7).

In step S503 (FIG. 24), the controller die CD acquires, from the memory die MD, the status data D_{ST} indicating whether the erase operation (FIG. 8) was completed successfully, as well as the loop count n_{E} of the erase loops executed up to the end of the erase operation (FIG. 8), as the loop count Lm.

In step S504 (FIG. 24), the controller die CD stores the loop count Lm acquired in step S503 in an area of a storing area MEM30 corresponding to the memory block BLK_m. The storing area MEM30 is, for example, RAM or the like provided in the controller die CD.

In FIG. 24, the loop count Lm is stored in the area corresponding to the m-th memory block BLK_m (where m is an integer greater than or equal to 0) in the storing area MEM30.

In the second embodiment, the memory die MD outputs the loop count Lm for the erase operation as the data D302 (described with reference to FIG. 13) instead of the count value Nm for the number of erase verification fail bits.

### Index (2) of Changes in Characteristics of Memory Cell MC

As described above, by repeating the write operation and the erase operation, more crystal defects and the like are generated inside the tunnel insulating film 131 (FIG. 5), resulting in the trapping of more electrons in the tunnel insulating film 131. In such a case, in step S204 of FIG. 8, in order for the erase verification to be determined as PASS, the erase voltage supply operation (FIG. 8, step S202) at a higher erase voltage V_{ERA} may be required. The erase voltage V_{ERA} increases by the offset voltage ΔV_{ERA} from the initial erase voltage V_{ERA0} as the loop count n_{E} increases, as shown in FIG. 9. Therefore, when the loop count n_{E} (loop count Lm) required to end the erase operation becomes large, it can be determined that more electrons are trapped in the tunnel insulating film 131 and that the characteristics of the memory cells MC are changing.

Therefore, the loop count Lm serves as an index of changes in the characteristics of the memory cells MC. The larger the loop count Lm, the more the threshold voltage distribution of the memory cells MC has shifted toward higher values, and it can thus be identified that characteristics are changing.

### Table 26b Showing Relationship Between Loop Count Lm and Magnitude of Initial Program Voltage V_{PGMS}

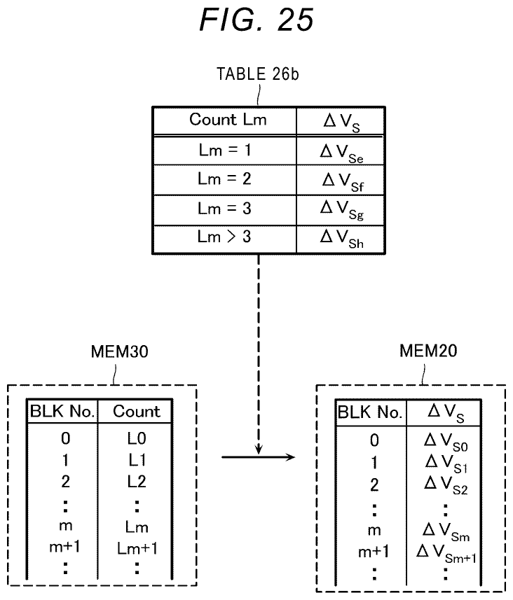

FIG. 25 is a diagram illustrating a table 26b and an example of its use. The table 26b is a table showing the relationship between the loop count Lm and the magnitude of the initial program voltage V_{PGMS}.

In FIG. 25, when the loop count Lm is 1, the offset voltage ΔV_{S} is set to an offset voltage ΔV_{Se}, when the loop count Lm is 2, the offset voltage ΔV_{S} is set to an offset voltage ΔV_{Sf}, when the loop count Lm is 3, the offset voltage ΔV_{S} is set to an offset voltage ΔV_{Sg}, and when the loop count Lm is greater than 3, the offset voltage ΔV_{S} is set to an offset voltage ΔV_{Sh}.

It is to be noted that in the table 26b, the offset voltages ΔV_{Se}, ΔV_{Sf}, ΔV_{Sg}, and ΔV_{Sh} may be negative values, and their absolute values may be the offset voltages ΔV_{Se}, ΔV_{Sf}, ΔV_{Sg}, and ΔV_{Sh} in ascending order. In this example, as the loop count Lm increases, the initial program voltage V_{PGMS} (=voltage V_{PGMS0}+ΔV_{S}) is set to be smaller.

As shown in the lower part of FIG. 25, by referring to the table 26b, the controller die CD acquires the offset voltage ΔV_{S} corresponding to the loop count Lm of each memory block BLK stored in the storing area MEM30, and stores the acquired offset voltage in the area of the storing area MEM20 corresponding to each memory block BLK_m.

### Third Embodiment

In the first and second embodiments, during the write operation, an initial program voltage V_{PGMS} of optimal magnitude is set according to the count value Nm or the loop count Lm.

In another example, an optimal program voltage application time T_{PGM} may be set according to the count value Nm or the loop count Lm. Hereinbelow, such an example will be described as the third embodiment.

### Write Flow

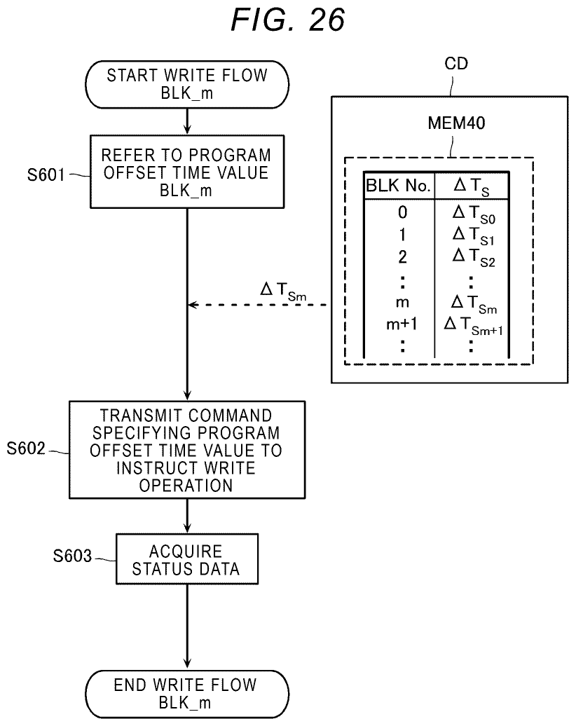

FIG. 26 is a flowchart illustrating the write flow according to the third embodiment. FIG. 26 shows the operation of the controller die CD when executing the write flow. In the following description, an example of executing a write operation on the memory cells MC provided in the memory block BLK_m will be described.

In step S601 (FIG. 26), the controller die CD refers to a storing area MEM40 and acquires the offset time ΔT_{S} corresponding to the memory block BLK_m. It is to be noted that, in the following description, the offset time ΔT_{S} corresponding to the memory block BLK_m may be referred to as an offset time ΔT_{Sm}. The storing area MEM40 is, for example, RAM or the like provided in the controller die CD.

In step S602 (FIG. 26), the controller die CD transmits a command specifying the offset time ΔT_{Sm} to the memory die MD and instructing a write operation (FIG. 15). As a result, in the memory die MD, the program voltage application time T_{PGM} obtained by adding the offset time ΔT_{Sm} to a reference program voltage application time T_{PGM0} is set, and the write operation (FIG. 15) is executed.

In step S603 (FIG. 26), the same operation as in step S303 (FIG. 14) is executed.

### Write Operation

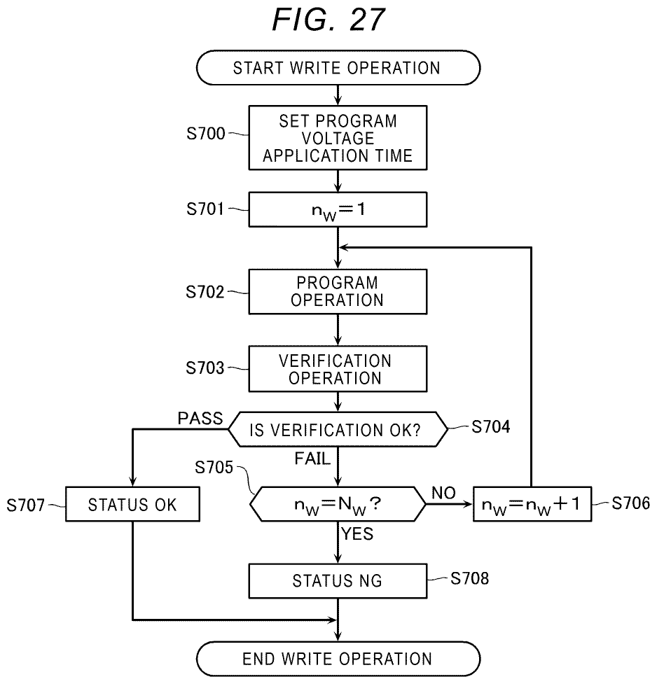

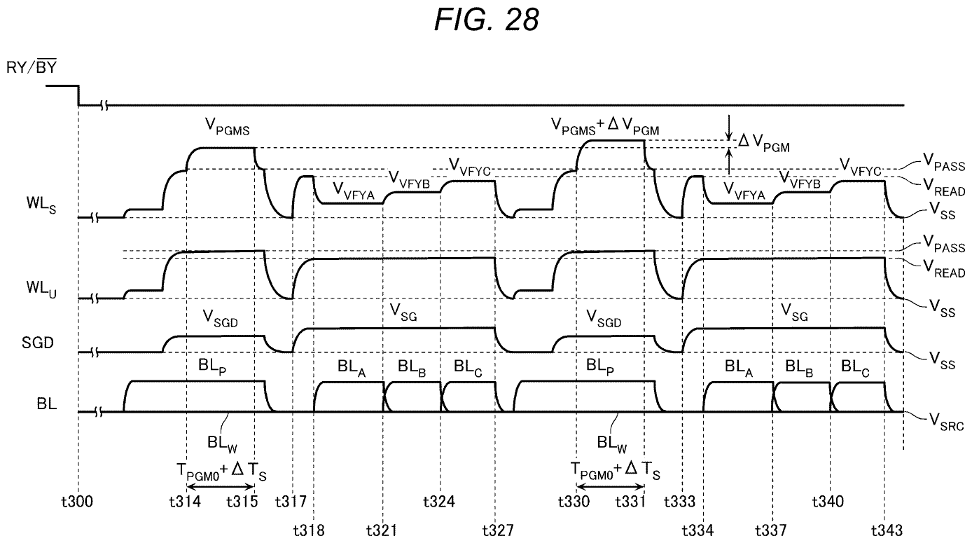

Next, the write operation of the memory system 10 according to the third embodiment will be described. FIG. 27 is a flowchart illustrating the write operation according to the third embodiment. FIG. 28 is a timing chart illustrating the program operation and the verification operation according to the third embodiment.

The write operation according to the third embodiment (FIG. 27) is basically the same as the write operation described for the first embodiment (FIG. 15), and steps S701 to S708 (FIG. 27) execute the same operations as steps S401 to S408 (FIG. 15). However, the write operation according to the third embodiment (FIG. 27) performs step S700 (FIG. 27) instead of step S400 (FIG. 15).

In Step S700, a Program Voltage Application Time Tpgm is set. The program voltage application time T_{PGM} is the application time for the program voltage V_{PGM1} during the program operation (step S402). The program voltage application time T_{PGM} is set to a time T_{PGM0}+ΔT_{S} obtained by adding the offset time ΔT_{S} specified in step S602 (FIG. 26) to the reference program voltage application time T_{PGM0}.

In the execution of the program operation in step S702, in the example of FIG. 28, a period from timing t314 to timing t315 and a period from timing t330 to timing t331 are set to the time T_{PGM0}+ΔT_{S}.

### Table 26c Showing Relationship Between Count Value Nm and Length of Program Voltage Application Time T_{PGM}

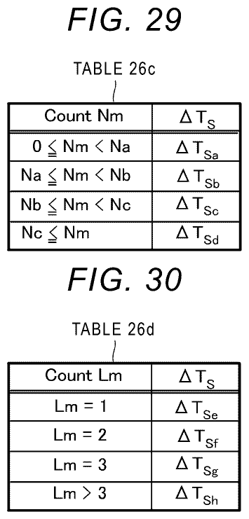

FIG. 29 is a diagram illustrating a table 26c. The table 26c is a table showing the relationship between the count value Nm and the length of program voltage application time T_{PGM}.

In FIG. 29, when the count value Nm is equal to or greater than index value 0 but less than the index value Na, the offset time ΔT_{S} is set to an offset time ΔT_{Sa}. When the count value Nm is equal to or greater than the index value Na but less than index value Nb, the offset time ΔT_{S} is set to an offset time ΔT_{Sb}. When the count value Nm is equal to or greater than the index value Nb but less than the index value Nc, the offset time ΔT_{S} is set to an offset time ΔT_{Sc}. When the count value Nm is equal to or greater than the index value Nc, the offset time ΔT_{S} is set to an offset time ΔT_{Sd}.

In the table 26c, the offset times ΔT_{Sa}, ΔT_{Sb}, ΔT_{Sc}, and ΔT_{Sd} may be negative values, for example, and the their absolute values may be the offset times ΔT_{Sa}, ΔT_{Sb}, ΔT_{Sc}, and ΔT_{Sd} in ascending order. In this example, as the count value Nm increases, the program voltage application time T_{PGM} (=time T_{PGM0}+ΔT_{S}) is set to be shorter.

By referring to the table 26c, the controller die CD acquires the offset time ΔT_{S} corresponding to the count value Nm for each memory block BLK stored in the storing area MEM10 (FIG. 7), and stores the acquired offset time in the storing area MEM40 (FIG. 26) corresponding to each memory block BLK_m.

For example, in FIG. 26, the offset time ΔT_{Sm} is stored the storing area MEM40 corresponding to the m-th memory block BLK_m.

### Table 26d Showing Relationship Between Loop Count Lm and Length of Program Voltage Application Time T_{PGM}

FIG. 30 is a diagram illustrating a table 26d. The table 26d shows the relationship between the loop count Lm and the length of the program voltage application time T_{PGM}.

In FIG. 30, when the loop count Lm is 1, the offset time ΔT_{S} is set to an offset time ΔT_{Se}, when the loop count Lm is 2, the offset time ΔT_{S} is set to an offset time ΔT_{Sf}, when the loop count Im is 3, the offset time ΔT_{S} is set to an offset time ΔT_{Sg}, and when the loop count Lm is greater than 3, the offset time ΔT_{S} is set to an offset time ΔT_{Sh}.

It is to be noted that in the table 26d, the offset times ΔT_{Se}, ΔT_{Sf}, ΔT_{Sg}, and ΔT_{Sh} may be negative values, for example, and their absolute values may be offset voltages ΔV_{Se}, ΔV_{Sf}, ΔV_{Sg}, and ΔV_{Sh} in ascending order. In this example, as the loop count Lm increases, the program voltage application time T_{PGM} (=time T_{PGM0}+ΔT_{S}) is set to be shorter.

By referring to the table 26d, the controller die CD acquires the offset time ΔT_{S} corresponding to the loop count Lm for each memory block BLK stored in the storing area MEM30 (FIG. 24), and stores the acquired offset time in storing area MEM40 (FIG. 26) for each memory block BLK_m.

### Other Embodiments

A memory system 10 according to certain example embodiments was described above. However, the above description is merely an example, and the configuration, operating method, and the like described above can be adjusted as appropriate.

For example, in the first to third embodiments, the magnitude of the initial program voltage V_{PGMS} or the length of the program voltage application time T_{PGM} is set according to the magnitude of the count value Nm or the loop count Lm. However, the magnitude of the initial program voltage V_{PGMS} or the length of the program voltage application time T_{PGM} may be set according to both the count value Nm and the loop count Lm. In addition, both the magnitude of the initial program voltage V_{PGMS} and the length of the program voltage application time T_{PGM} may be set according to the magnitude of either one or both of the count value Nm and the loop count Lm.

In the first to third embodiments, the count value Nm and/or the loop count Lm are stored for each memory block BLK_m in the storing area MEM10 (FIG. 7) and the storing area MEM30 (FIG. 24), respectively, and the magnitude of the initial program voltage V_{PGMS} and the length of the program voltage application time T_{PGM} are set for each memory block BLK_m. However, the unit for storing the count value Nm and the loop count Lm, and the unit for setting the magnitude of the initial program voltage V_{PGMS} and the length of the program voltage application time T_{PGM}, need not necessarily be on individual memory block BLK_m basis, but, rather than a per block basis, a multiple block unit size may be adopted when a value is shared by a plurality of memory blocks BLK_m.

In addition, as a method for the controller die CD to acquire the count value Nm and the loop count Lm from the memory die MD, in steps S102 and S103 (FIG. 7) and steps S502 and S503 (FIG. 24), the method of acquiring the count value Nm and the loop count Lm at the same time as the status data D_{ST} in a status read operation was illustrated. However, the method for acquiring the count value Nm and the loop count Lm can be adjusted appropriately, and for example, the count value Nm and the loop count Lm may be acquired by a dedicated command set to be other than a status read operation command.

In an embodiment, the number of fail bits was counted in units of memory string MS, but alternatively, it is possible to count whether the erase verification failed or not in units of memory cells MC provided in the memory string MS. In this case, the number of fail bits is the number of memory cells MC for which the erase verification failed.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory system, comprising:
a semiconductor memory device; and
a control device connected to the semiconductor memory device, wherein
the semiconductor memory device includes:
a plurality of conductive layers spaced from each other in a first direction;
a semiconductor pillar extending in the first direction in the plurality of conductive layers;
a charge storage layer between the plurality of conductive layers and the semiconductor pillar; and
a wiring electrically connected to one end of the semiconductor pillar,
the control device is configured to:
instruct a write operation and an erase operation of the semiconductor memory device,
the write operation includes a plurality of write loops,
each of the write loops includes a program operation of supplying a program voltage to a conductive layer of the plurality of conductive layers,
the program voltage increases by an offset voltage from an initial program voltage as the number write loops increases in the write operation,
the erase operation includes a plurality of erase loops,
each of the erase loops includes:
an erase voltage supply operation of supplying an erase voltage to the wiring; and
an erase verification operation executed after the erase voltage supply operation is performed,
the semiconductor memory device is configured to output first data corresponding to an execution result of the erase verification operation to the control device, and
when executing the write operation, the control device refers to a table indicating a relationship between the first data and a magnitude to be used for the initial program voltage and transmits second data indicating the initial program voltage corresponding to the first data in the table to the semiconductor memory device.

2. The memory system according to claim 1, wherein the first data is the number of fail bits in the erase verification operation.

3. The memory system according to claim 2, wherein, in the table, the greater the number of fail bits in the erase verification operation, the smaller the magnitude of the initial program voltage corresponding thereto.

4. The memory system according to claim 1, wherein the first data is the number of erase loops executed in the erase operation.

5. The memory system according to claim 4, wherein, in the table, the greater the number of erase loops, the smaller the magnitude of the initial program voltage corresponding thereto.

6. The memory system according to claim 1, wherein
the semiconductor memory device includes a plurality of memory blocks, and
the semiconductor memory device is configured to output the first data for each of the memory blocks.

7. The memory system according to claim 1, wherein the semiconductor memory device outputs the first data to the control device in response to a command instructing a status read operation.

8. A memory system, comprising:
a semiconductor memory device; and
a control device connected to the semiconductor memory device, wherein
the semiconductor memory device includes:
a plurality of conductive layers spaced from each other in a first direction;
a semiconductor pillar extending in the first direction in the plurality of conductive layers;
a charge storage layer between the plurality of conductive layers and the semiconductor pillar; and
a wiring electrically connected to one end of the semiconductor pillar,
the control device is configured to:
instruct a write operation and an erase operation of the semiconductor memory device,
the write operation includes a plurality of write loops,
each of the write loops includes a program operation of supplying a program voltage to a conductive layer of the plurality of conductive layers,
the program voltage increases by an offset voltage from an initial program voltage as the number of write loops increases in the write operation,
the erase operation includes a plurality of erase loops,
each of the erase loops includes:
an erase voltage supply operation of supplying an erase voltage to the wiring; and
an erase verification operation executed after the erase voltage supply operation is performed,
the semiconductor memory device is configured to output the number of erase loops executed in the erase operation to the control device, and
the control device is configured to adjust a magnitude of the initial program voltage in the write operation according to the output number of erase loops.

9. The memory system according to claim 8, wherein the control device is configured to reduce the magnitude of the initial program voltage as the output number erase loops increases.

10. The memory system according to claim 8, wherein
the semiconductor memory device includes a plurality of memory blocks, and
the semiconductor memory device is configured to output the number of erase loops for each the memory blocks.

11. The memory system according to claim 8, wherein the semiconductor memory device outputs the number of erase loops to the control device in response to a command instructing a status read operation.

12. A memory system, comprising:
a semiconductor memory device; and
a control device connected to the semiconductor memory device, wherein
the semiconductor memory device includes:
a plurality of conductive layers spaced from each other in a first direction;
a semiconductor pillar extending in the first direction in the plurality of conductive layers;
a charge storage layer between the plurality of conductive layers and the semiconductor pillar; and
a wiring electrically connected to one end of the semiconductor pillar,
the control device is configured to:
instruct a write operation and an erase operation of the semiconductor memory device,
the write operation includes a plurality of write loops,
each of the write loops includes a program operation of supplying a program voltage to a conductive layer of the plurality of conductive layers,
the program voltage increases by an offset voltage from an initial program voltage as the number of write loops increases in the write operation,
the erase operation includes a plurality of erase loops,
each of the plurality of erase loops includes:
an erase voltage supply operation of supplying an erase voltage to the wiring; and
an erase verification operation executed after the erase voltage supply operation is performed,
the semiconductor memory device is configured to output first data corresponding to an execution result of the erase verification operation to the control device, and
the control device is configured to adjust an application time for the program voltage in the program operation in accordance with the first data.

13. The memory system according to claim 12, wherein the first data is the number of fail bits in the erase verification operation.

14. The memory system according to claim 13, wherein the control device reduces the application time for the program voltage as the number of fail bits in the erase verification operation increases.

15. The memory system according to claim 12, wherein the first data is the number of erase loops executed in the erase operation.

16. The memory system according to claim 15, wherein the control device reduces the application time for the program voltage as the number of erase loops increases.

17. The memory system according to claim 12, wherein
the semiconductor memory device includes a plurality of memory blocks, and
the semiconductor memory device is configured to output the first data for each of the memory blocks.

18. The memory system according to claim 12, wherein the semiconductor memory device outputs the first data to the control device in response to a command instructing a status read operation.
